(19) United States
(12) Patent Application Publication
(10) Pub. No.: US 2026/0029432 A1
(43) Pub. Date: Jan. 29, 2026

(54) INTERFACE PROBE CARD WITH UNOBSTRUCTED PHYSICAL AND OPTICAL ACCESS TO A DEVICE UNDER TEST AND PROBING A DEVICE UNDER TEST WITH SAME

(71) Applicant: Government of the United States of America, as represented by the Secretary of Commerce, Gaithersburg, MD (US)

(72) Inventors: William Horrocks Rippard, V, Boulder, CO (US); Matthew Read Pufall, Boulder, CO (US); Ian Whitney Haygood, Louisville, CO (US); Michael Lindsay Schneider, Superior, CO (US)

(21) Appl. No.: 19/284,111

(22) Filed: Jul. 29, 2025

Related U.S. Application Data
(60) Provisional application No. 63/676,477, filed on Jul. 29, 2024.

(51) Int. Cl. G01R 1/073; G01R 1/067; G01R 3/00; G01R 31/28

(52) U.S. Cl. CPC G01R 1/07342; G01R 1/06733; G01R 3/00; G01R 31/2889

(57) ABSTRACT

An interface probe card includes a planar dielectric substrate of a cryogenic-compatible material having a first major surface and an opposite second major surface. Disposed on the first major surface is a plurality of high-speed conductive traces. A plurality of inner contact pads, also on the first major surface, are electrically connected to the conductive traces and arranged in a geometric pattern that defines an interior region. A plurality of metallic bumps protrude from the inner contact pads. Located within the interior region defined by the geometric pattern is an aperture that extends entirely through the planar dielectric substrate from the first major surface to the second major surface, providing an unobstructed line-of-sight path.

### CROSS-REFERENCE TO RELATED APPLICATION

This application claims the benefit of U.S. Provisional Patent Application Ser. No. 63/676,477 (filed Jul. 29, 2024), which is herein incorporated by reference in its entirety.

### STATEMENT REGARDING FEDERALLY SPONSORED RESEARCH

This invention was made with United States Government support from the National Institute of Standards and Technology (NIST), an agency of the United States Department of Commerce. The Government has certain rights in this invention.

### BACKGROUND

The present invention generally relates to the field of testing and metrology for microelectronic devices, and more particularly to techniques for providing a high-bandwidth, cryogenic-compatible interface to a device under test that affords simultaneous and unobstructed physical and optical access for advanced microscopy.

The relentless scaling of microelectronic devices, particularly in emergent fields such as superconducting electronics and quantum information science, has created an urgent and unmet need for advanced metrology and characterization techniques. The successful development and fault analysis of these next-generation circuits, which often operate at profoundly low cryogenic temperatures and at frequencies exceeding tens or even hundreds of gigahertz, depend critically on the ability to probe their physical and electrical properties in-situ and under active operational conditions. This requirement pushes the boundaries of conventional test equipment, demanding new paradigms for interfacing with these complex and sensitive systems.

The established method for establishing an electrical link to a device under test (DUT) within a controlled environment, such as a cryostat, involves the use of a probe card. This indispensable tool serves as a transitional interface, bridging the macroscopic world of room-temperature test instrumentation with the microscopic domain of the DUT. A conventional probe card typically consists of a substrate material, upon which conductive traces are patterned to route high-frequency signals from external connectors to an array of contact points-such as metallic needles or bumps—that physically touch the contact pads of the DUT, thereby completing the electrical circuit for testing.

However, the architectures of prior-art probe cards are fundamentally at odds with the requirements of modern, high-resolution microscopy. These conventional probe cards are characterized by their significant physical bulk and high profile. This considerable thickness, often on the order of millimeters, inherently creates a substantial standoff distance and, more critically, a massive physical overhang that completely obscures the active surface of the DUT. This obstruction forms an insurmountable barrier to any form of top-down microscopy that requires a direct line of sight or close physical proximity, such as scanned SQUID (superconducting quantum interference device) microscopy, atomic force microscopy (AFM), or high-numerical-aperture optical inspection. Consequently, researchers are faced with a frustrating dilemma: they can either perform electrical testing with the DUT obscured or perform microscopy on an inactive, disconnected device, but they cannot effectively do both simultaneously. This limitation severely hampers the ability to correlate electrical performance with physical phenomena or to perform real-time failure analysis on active circuits.

It is therefore an objective of the present invention to provide a probe card that enables simultaneous high-bandwidth electrical probing and direct, close-proximity physical access to the surface of a device under test, thereby overcoming the above-mentioned disadvantages of the prior art at least in part. Accordingly, a probe card architecture that harmonizes high-frequency electrical testing with unobstructed, in-situ metrology would be advantageous and would be favorably received in the art.

### BRIEF DESCRIPTION

One aspect of the present invention relates to an interface probe card. An interface probe card may be understood as an electromechanical apparatus that serves as a physical, optical, and electrical bridge between a test instrument and a microelectronic device, such as an integrated circuit or a device under test (DUT), facilitating the transmission of electrical signals for characterization and analysis.

It may be provided that the interface probe card comprises a planar dielectric substrate having a first major surface and a second major surface opposite the first major surface, wherein the planar dielectric substrate is a cryogenic-compatible material. A planar dielectric substrate may be understood as a substantially flat, non-conductive mechanical support structure for electronic components, while a cryogenic-compatible material is a substance capable of maintaining its essential mechanical and electrical properties at temperatures below approximately 123 K. This arrangement provides a dimensionally stable and electrically insulating foundation that ensures structural integrity and reliable low-loss signal propagation even under the extreme temperature cycling required for testing superconducting and other advanced cryogenic devices, an improved functionality that is not achievable with conventional substrate materials that become brittle or exhibit degraded dielectric performance at such low temperatures.

It may be provided that the interface probe card comprises a plurality of high-speed conductive traces disposed on the first major surface of the substrate. High-speed conductive traces may be understood as patterned metallic pathways engineered to transmit electrical signals, often in the gigahertz range, with minimal loss, distortion, and crosstalk. The disposition of a plurality of such traces on the substrate surface enables the creation of a dense, multi-channel interface with superior performance metrics, accommodating the high bandwidth necessary for accurately characterizing the operational parameters of modern, high-frequency circuits.

It may be provided that the interface probe card comprises a plurality of inner contact pads disposed on the first major surface, wherein each inner contact pad of the plurality of inner contact pads is electrically connected to at least one of the plurality of high-speed conductive traces, the plurality of inner contact pads arranged in a geometric pattern that defines an interior region. Inner contact pads may be understood as distinct metallic areas serving as the terminal points for the conductive traces, which are organized into a specific, non-random spatial configuration, or geometric pattern. This arrangement provides a precise and repeatable architecture for interfacing with a DUT, while the geometric pattern's definition of an interior region establishes a novel structural foundation for a dedicated, unobstructed access zone, which enhances the reliability of the probing process.

It may be provided that the interface probe card comprises a plurality of metallic bumps, each metallic bump of the plurality of metallic bumps protruding from one of the plurality of inner contact pads. Metallic bumps may be understood as three-dimensional conductive structures, such as deposited pillars, that extend outward from the planar surface of the contact pads. The protuberant nature of these bumps provides a compliant and robust physical interface that can accommodate minute non-planarity between the probe card and the DUT, ensuring that a reliable, low-resistance electrical connection is made across the entire array of contacts, a more efficient and accurate method for achieving a multi-point connection.

It may be provided that the interface probe card comprises an aperture extending entirely through the planar dielectric substrate from the first major surface to the second major surface, the aperture located within the interior region defined by the geometric pattern of the plurality of inner contact pads, wherein the aperture provides an unobstructed line-of-sight path through the substrate. An aperture may be understood as a through-hole. This arrangement provides a new and unique solution to the problem of physical obstruction inherent in the prior art; its location within the interior region defined by the pads, coupled with its complete passage through the substrate, creates an unprecedented, direct physical and optical pathway to the active surface of a DUT. This improved functionality enables a new class of in-situ analyses, allowing advanced microscopy probes to be positioned in close proximity to a device while it is electrically active, providing a practical application and utility not achievable with conventional probe card designs.

One aspect of the present invention relates to a method for probing a device under test. A method for probing a device under test may be understood as a sequence of operations performed to characterize the electrical and physical properties of a microelectronic component, often to verify its performance or diagnose faults.

It may be provided that the method comprises providing an interface probe card comprising a planar dielectric substrate having a first major surface and an opposing second major surface, a plurality of high-speed conductive traces on the first major surface, a plurality of inner contact pads electrically connected to the plurality of high-speed conductive traces and arranged to define an interior region, a plurality of metallic bumps protruding from the plurality of inner contact pads, and an aperture extending entirely through the substrate within the interior region. Providing may be understood as supplying or making available for use. This step furnishes the unique hardware foundation upon which the subsequent novel process steps can be executed; the specific structure of the probe card, particularly its aperture circumscribed by contact pads, is a prerequisite that enables the concurrent electrical and physical analysis that was previously unattainable.

It may be provided that the method comprises aligning a device under test (DUT) with the plurality of inner contact pads. Aligning may be understood as positioning two or more components into a precise spatial correspondence. This step ensures that each metallic bump on the probe card is accurately juxtaposed with its intended counterpart contact on the DUT, a critical precursor for establishing a uniform and reliable electrical connection across the entire interface, thereby performing the task of creating multiple connections more accurately and reliably than methods lacking such precision.

It may be provided that the method comprises establishing simultaneous mechanical and electrical communication between the plurality of metallic bumps and a corresponding plurality of contacts on the device under test (DUT). Simultaneous mechanical and electrical communication may be understood as the creation of a physical interconnection that also serves as a pathway for the flow of electrical current. This arrangement provides improved functionality by creating a stable, integrated assembly where the DUT is both physically secured and electrically addressable, allowing for dependable testing without risk of intermittent connections or misalignment during subsequent handling or analysis.

It may be provided that the method comprises accessing a surface of the device under test (DUT) with a microscopy probe through the aperture of the interface probe card while the mechanical and electrical communication is maintained. A microscopy probe may be understood as the sensing element of a high-magnification instrument that interacts with a sample surface to acquire data. This step provides a new and unique solution to a long-standing problem in the art by leveraging the probe card's aperture to create a direct, unobstructed path for the microscopy probe to reach the DUT's active surface. This novel process provides the utility of performing in-situ, high-resolution physical analysis on a fully powered and operational device, representing a significant enhancement in performance that allows for the direct correlation of electrical signals with physical phenomena, a task that could not be performed with prior art methods.

One aspect of the present invention relates to a method for fabricating an interface probe card. A method for fabricating an interface probe card may be understood as a controlled sequence of microfabrication processes designed to construct a specialized electromechanical apparatus for testing microelectronic devices.

It may be provided that the method comprises providing a planar dielectric substrate having a first major surface and a second major surface opposite the first major surface. Providing a planar dielectric substrate establishes the foundational workpiece upon which all subsequent features are built. This arrangement ensures that the fabrication process begins with a material of known mechanical stability and electrical insulating properties, which provides for enhanced performance and reliability in the final device by guaranteeing dimensional accuracy for the high-precision features to be formed thereon.

It may be provided that the method comprises depositing a layer of a conductive material onto the first major surface of the planar dielectric substrate. Depositing a layer of a conductive material may be understood as the application of a uniform, electrically conductive film, for instance through techniques like sputtering or evaporation. This step creates the raw material for the device's electrical pathways; by starting with a continuous and well-controlled conductive layer, the process enables the subsequent formation of transmission lines with consistent electrical characteristics, which improves the functionality and high-frequency performance of the completed probe card.

It may be provided that the method comprises patterning the layer of the conductive material to define a plurality of high-speed conductive traces and a plurality of inner contact pads, each of the plurality of inner contact pads electrically connected to at least one of the plurality of high-speed conductive traces, wherein the plurality of inner contact pads circumscribe an interior region of the first major surface. Patterning may be understood as the selective removal of material to form a specific design. This arrangement performs the task of creating the electrical infrastructure more efficiently by simultaneously forming the signal routing pathways and the precise terminal contact points in a single coordinated step, while the act of circumscribing an interior region establishes the critical geometric boundary necessary for the subsequent formation of the access path.

It may be provided that the method comprises depositing a plurality of metallic bumps, wherein each metallic bump of the plurality of metallic bumps is deposited onto one of the plurality of inner contact pads. This step provides the practical application of adding a three-dimensional contact structure to the planar pads. The formation of these protuberant features is essential for creating a compliant and robust mechanical interface capable of ensuring reliable, low-resistance electrical connections when mated with a device under test, a more accurate method for achieving a multi-point connection than planar contacts alone.

It may be provided that the method comprises, after depositing the plurality of metallic bumps, etching entirely through the planar dielectric substrate from the first major surface to the second major surface to form an aperture located within the interior region. Etching entirely through the substrate may be understood as a material removal process that creates a complete through-hole. The specific sequence of performing this high-impact etching step after the formation of the delicate surface features provides a new and unique solution to manufacturing such a device; this arrangement maintains the full mechanical integrity of the substrate during the precision lithography and deposition steps, preventing warping or damage that could misalign the conductive traces and bumps, thereby performing the overall fabrication task more reliably and ensuring superior final device quality.

### BRIEF DESCRIPTION OF THE DRAWINGS

The following description cannot be considered limiting in any way. Various objectives, features, and advantages of the disclosed subject matter can be more fully appreciated with reference to the following detailed description of the disclosed subject matter when considered in connection with the following drawings, in which like reference numerals identify like elements.

FIG. 1 shows, according to some embodiments, a top-down schematic view of an interface probe card illustrating the layout of high-speed co-planar waveguide leads radiating from a contact area.

FIG. 2 shows, according to some embodiments, a composite view illustrating a design schematic, a photograph of a fabricated and bonded probe card assembly, and a reverse-side photograph showing the device under test visible through the aperture.

FIG. 3 shows, according to some embodiments, a composite view with photographs of the interface probe card implemented within a test fixture and a graph presenting high-frequency scattering parameter data for the apparatus.

FIG. 4 shows, according to some embodiments, a composite view including a photograph of the interface probe card's usage within a scanned SQUID microscope and corresponding schematic cross-sectional diagrams illustrating the probe-to-device interface.

FIG. 5 shows, according to some embodiments, a set of schematic views of the region of the interface probe card, including a close-up top view of the aperture (labelled as optical window), an enlarged view of a single inner contact pad with metallic bumps, and a side cross-sectional view of the area.

FIG. 6 shows, according to some embodiments, a schematic side cross-sectional view of an area of the interface probe card close to the inner contact bumps, illustrating the vertical structure of the substrate, a compliant region, and the aperture.

FIG. 7 shows, according to some embodiments, a schematic top-down view of an alternative implementation of the interface probe card featuring individual micromachined flexures with hard metal contacts arranged around an optical window.

FIG. 8 shows, according to some embodiments, a schematic flowchart illustrating a sequence of microfabrication process steps for manufacturing the interface probe card, depicted through a series of cross-sectional views.

FIG. 9 shows, according to some embodiments, a flowchart illustrating a method for probing a device under test utilizing the unique features of the interface probe card.

FIG. 10 shows, according to some embodiments, a flowchart illustrating a method for fabricating the interface probe card, detailing a specific sequence of deposition and etching operations.

### DETAILED DESCRIPTION

A detailed description of one or more embodiments is presented herein by way of exemplification and not limitation.

Conventional techniques for interfacing with microelectronic devices are beset by fundamental architectural limitations that have created a significant technological bottleneck, particularly in the investigation of advanced, high-performance circuits. The standard tools, known as probe cards, are required to establish electrical communication for testing, but their inherent physical design is one of considerable bulk and high profile. This structural massiveness results in a large physical overhang that completely occludes the active surface of the device under test. This obstruction makes it impossible to perform any form of high-resolution, top-down microscopy, such as scanned SQUID or atomic force microscopy, on a device while it is electrically active and operating. Researchers are thus forced into a compromised position, able to either perform electrical measurements on an obscured device or physical analysis on a disconnected, inactive one, but critically unable to perform these tasks simultaneously to correlate physical phenomena with real-time electrical behavior.

The interface probe card overcomes these deficiencies of physical obstruction and the preclusion of simultaneous electrical and physical analysis.

It has been discovered that an interface probe card can be constructed to provide a solution that reconciles the historically conflicting requirements of high-density, high-frequency electrical interconnection and completely unobstructed physical access to a device under test. One advantage of the interface probe card lies in its novel structure. The provision of an aperture that extends entirely through the planar dielectric substrate provides a direct, unmediated line-of-sight path to the device under test. The specific location of this aperture within the interior region defined by the geometric pattern of the inner contact pads is a unique arrangement that offers an unprecedented utility: the ability to position a physical microscopy probe in extremely close proximity to the active surface of a device while that same device is fully connected and electrically stimulated via the surrounding contact pads. This improved functionality enables a new class of in-situ experiments and failure analysis not possible with prior art designs. The utility of this architecture is profoundly amplified by the composition of the planar dielectric substrate from a cryogenic-compatible material, which ensures the probe card maintains its mechanical and electrical integrity at the profoundly low temperatures required for testing superconducting and quantum circuits. This arrangement provides for enhanced performance by allowing the novel physical access to be leveraged in the most technologically demanding environments. The integration of a plurality of high-speed conductive traces ensures that the electrical signals transmitted to the device under test are of high fidelity and bandwidth, allowing for the accurate characterization of circuits operating at gigahertz frequencies. Finally, the use of protruding metallic bumps for the electrical interface provides a more reliable and compliant connection scheme, accommodating microscopic surface variations to ensure uniform contact across the entire array, thereby performing the task of creating multiple parallel connections more accurately and reliably.

In an embodiment, an interface probe card comprises a planar dielectric substrate (1) having a first major surface and a second major surface opposite the first major surface, wherein the planar dielectric substrate (1) is a cryogenic-compatible material, a plurality of high-speed conductive traces (2) disposed on the first major surface of the substrate (1), a plurality of inner contact pads (3) disposed on the first major surface, wherein each inner contact pad of the plurality of inner contact pads (3) is electrically connected to at least one of the plurality of high-speed conductive traces (2), the plurality of inner contact pads (3) arranged in a geometric pattern that defines an interior region, a plurality of metallic bumps (4), each metallic bump of the plurality of metallic bumps (4) protruding from one of the plurality of inner contact pads (3), and an aperture (6) extending entirely through the planar dielectric substrate (1) from the first major surface to the second major surface, the aperture (6) located within the interior region defined by the geometric pattern of the plurality of inner contact pads (3), wherein the aperture (6) provides an unobstructed line-of-sight path through the substrate (1). In an embodiment, the planar dielectric substrate (1) is single-crystal silicon. In an embodiment, the planar dielectric substrate (1) has a thickness of less than 400 micrometers. In an embodiment, the plurality of high-speed conductive traces (2) are co-planar waveguides. In an embodiment, the co-planar waveguides comprise a superconductive material. In an embodiment, the superconductive material is niobium. In an embodiment, the plurality of metallic bumps (4) comprise indium. In an embodiment, a portion of the substrate (1) proximate to the plurality of inner contact pads (3) has a reduced thickness relative to other portions of the substrate (1), thereby forming a compliant region (5). In an embodiment, the geometric pattern of the plurality of inner contact pads (3) is a perimeter array that peripherally surrounds the aperture (6). In an embodiment, the planar dielectric substrate (1) is single-crystal silicon, the plurality of high-speed conductive traces (2) are co-planar waveguides comprising niobium, and the plurality of metallic bumps (4) comprise indium.

The interface probe card incorporates a planar dielectric substrate (1) that serves as the foundational mechanical support and electrical isolation layer for all other components. The functionality of the substrate (1) is to provide a dimensionally stable and non-conductive platform that maintains its integrity across a vast temperature range, from ambient conditions down to the millikelvin regime. In one implementation, the substrate (1) is a single-crystal silicon wafer, for example, one with a thickness of approximately 380 micrometers, although thinner substrates (1), potentially as thin as 5 micrometers, may be used to further reduce the device profile. A benefit of this implementation is that silicon exhibits exceptionally low dielectric loss at high frequencies and cryogenic temperatures, ensuring superior performance by preserving the integrity of signals transmitted across it. The use of a cryogenic-compatible material is a practical application that provides improved reliability, preventing mechanical failure from thermal shock or mismatched coefficients of thermal expansion when the entire assembly is cooled. Variations may include the use of other low-loss, cryogenic-compatible dielectric materials such as sapphire or high-purity quartz for the substrate (1).

Disposed upon the first major surface of the substrate (1) is a plurality of high-speed conductive traces (2). The function of these traces (2) is to act as transmission lines, routing electrical signals from the periphery of the probe card to the test area. These traces (2) are implemented by patterning a deposited layer of a conductive material, such as niobium, using standard photolithography and reactive ion etching techniques to form high-performance structures like co-planar waveguides. One benefit of this arrangement is the enhanced performance in high-frequency signal transmission, with such structures demonstrated to operate with low loss at frequencies exceeding 100 GHz. A further example of use involves employing a superconductive material like niobium for the traces (2), which, when operated below its critical temperature, provides nearly lossless signal conduction, offering an improved functionality critical for the low-power, high-sensitivity measurements required in quantum computing and superconducting electronics. Alternative implementations could utilize non-superconducting metals like gold or copper or different planar waveguide geometries like microstrip or stripline, depending on the specific application's frequency and temperature requirements.

The high-speed conductive traces (2) terminate at a plurality of inner contact pads (3), which are also disposed on the first major surface. The function of these pads (3) is to provide a well-defined interface point for making an electrical connection to the device under test. They are arranged in a geometric pattern, such as a rectangular perimeter array, which defines an interior region on the substrate (1). This arrangement provides the utility of a standardized, high-density landing zone for DUT contacts. A primary benefit of arranging the pads (3) to circumscribe an interior region is the novel creation of a dedicated, unobstructed zone, which is a structural prerequisite for the line-of-sight access path. This configuration represents a non-obvious solution to integrating high-density I/O with direct physical access.

Protruding from each of the inner contact pads (3) is one of a plurality of metallic bumps (4). The function of these bumps (4) is to form the final, three-dimensional physical and electrical connection to the corresponding pads on a DUT. They are typically implemented by depositing a soft, malleable metal, such as indium, onto the pads (3) using a process like thermal evaporation combined with a lift-off mask. The benefit of these protuberant structures is improved reliability in the connection process; their compliance accommodates microscopic variations in planarity between the probe card and the DUT, ensuring that a uniform, low-resistance electrical contact is established across all pads when pressure is applied. An example of their use is in a die-bonding process where the indium bumps (4) are compressed against the DUT pads, forming a stable, semi-permanent cold-weld bond that is robust even at cryogenic temperatures. Alternative implementations could involve bumps (4) made from other metals or hard-metal contacts integrated with individually micromachined flexures.

The interface probe card further comprises an aperture (6) that extends entirely through the planar dielectric substrate (1). This aperture (6) is located within the interior region that is defined by the geometric pattern of the inner contact pads (3), and its structure provides an unobstructed line-of-sight path through the substrate (1). The functionality of the aperture (6) is to create a physical void, a gateway that fundamentally overcomes the limitations of prior art. The aperture (6) can be arranged in any position of the interface probe card to function as an unobstructed line-of-sight via to the device under test. It is contemplated that the aperture (6) can be centrally located in the middle of the interface probe card or off-center, depending on geometrical, physical, electrical, thermal, or optical constraints or considerations. It is implemented using a deep reactive ion etching process that removes the substrate material in the zone after the front-side conductive features have been fabricated. The benefit of this feature is a new and unique solution providing an unprecedented utility: it allows a microscopy probe, such as a SQUID sensor or an AFM tip, to be positioned directly over, and in close proximity to, the active surface of the DUT while the DUT is simultaneously being electrically probed via the surrounding pads (3) and bumps (4). This improved functionality enables a new domain of in-operando testing and metrology, performing a task that was previously impossible, thereby providing a practical and powerful tool for research and development in advanced microelectronics.

In some embodiments, the planar dielectric substrate (1) is single-crystal silicon. The use of single-crystal silicon as the substrate (1) material offers a well-characterized and highly manufacturable platform. A significant benefit of this implementation is the material's outstanding electrical and mechanical properties at cryogenic temperatures; silicon maintains low dielectric loss at gigahertz frequencies and exhibits excellent dimensional stability during thermal cycling, which provides for enhanced performance and reliability of the high-speed conductive traces (2) it supports. Its compatibility with mature semiconductor fabrication techniques, such as deep reactive ion etching, allows for the precise and repeatable formation of the device's features, making the manufacturing process more efficient and accurate.

In some embodiments, the planar dielectric substrate (1) has a thickness of less than 400 micrometers. Constraining the vertical dimension of the substrate (1) to such a low profile is a novel feature that distinguishes the apparatus from conventional, millimeter-scale probe cards. This reduced thickness offers the benefit of minimizing the physical standoff distance between a microscopy probe and the device under test, which improves the functionality of the associated measurement by enhancing the potential resolution and signal-to-noise ratio. The thin structure also has a lower thermal mass, which provides for more efficient operation by enabling faster cooling and warming cycles within a cryogenic test environment.

In some embodiments, the plurality of high-speed conductive traces (2) are co-planar waveguides. This specific geometry, where a signal conductor is flanked on the same plane by ground conductors, provides a superior performance metric by effectively confining the electromagnetic fields. This field confinement minimizes signal loss, dispersion, and crosstalk between adjacent traces (2), enabling the reliable transmission of high-bandwidth signals. The utility of this structure is that it allows for the accurate characterization of circuits operating at frequencies in excess of 100 GHz, a task performed more accurately than with other trace geometries.

In some embodiments, the co-planar waveguides comprise a superconductive material. The use of a superconductor provides for enhanced performance by dramatically reducing electrical losses when the apparatus is operated below the material's critical temperature. This improved functionality results from the near-zero DC resistance and extremely low RF surface resistance of the superconductor, which ensures that signals, particularly those for low-power devices, are transmitted with the highest possible fidelity and minimal introduction of thermal noise from the interface card itself.

In some embodiments, the superconductive material is niobium. The selection of niobium provides a practical application for use in common cryogenic systems. A benefit of niobium is its critical temperature of approximately 9.2 Kelvin, which is well above the operating temperature of liquid helium (4.2 K), making it highly suitable for a wide range of superconducting electronics testing. Furthermore, niobium is a robust material with well-established deposition and etching processes, leading to more reliable and repeatable manufacturing outcomes.

In some embodiments, the plurality of metallic bumps (4) comprise indium. The functionality of using indium for the bumps (4) is to create a highly compliant and reliable electromechanical interface. Indium's extreme malleability, which persists even at deep cryogenic temperatures, is a benefit that allows the bumps (4) to conform to microscopic surface irregularities, ensuring that a uniform, low-resistance electrical contact is made across the entire array. The material also readily forms cold-weld bonds under compression, providing for superior durability and a mechanically robust connection that withstands repeated thermal cycling.

In some embodiments, a portion of the substrate (1) proximate to the plurality of inner contact pads (3) has a reduced thickness relative to other portions of the substrate (1), thereby forming a compliant region (5). The functionality of this compliant region (5) is to introduce localized mechanical flexibility into the otherwise rigid substrate (1). This provides the benefit of an engineered deflection zone, which allows the probe card to be slightly overdriven during contact without imparting excessive, potentially damaging force onto the device under test. This improved functionality ensures a more uniform contact pressure and makes the overall interconnection process more reliable, particularly when interfacing with large or non-planar devices.

In some embodiments, the geometric pattern of the plurality of inner contact pads (3) is a perimeter array that peripherally surrounds the aperture (6). This spatial arrangement provides the utility of maximizing the available area within the aperture (6), which improves the functionality of the device by providing the largest possible, unobstructed field of view for microscopy. The perimeter layout also offers a clear and organized topology for routing the conductive traces (2) radially inward, a configuration that can help minimize trace length and mitigate signal integrity issues.

In some embodiments, the planar dielectric substrate (1) is single-crystal silicon, the plurality of high-speed conductive traces (2) are co-planar waveguides comprising niobium, and the plurality of metallic bumps (4) comprise indium. The specific combination of these materials and structures represents a synergistic system optimized for the most demanding applications. This arrangement provides for enhanced performance by leveraging the low-loss properties of the silicon substrate (1), the nearly lossless nature of the superconducting niobium traces (2), and the compliant, reliable interface of the indium bumps (4), creating a novel and non-obvious interface solution with superior performance metrics for the high-frequency, cryogenic testing of advanced electronic circuits.

A feature of the interface probe card is the aperture (6), a physical void that extends entirely through the planar dielectric substrate (1). This aperture (6) is strategically located within an interior region defined by the geometric arrangement of the plurality of inner contact pads (3), which typically form a perimeter array around this opening. This structural configuration provides a direct, unmediated physical and optical pathway from the second major surface of the substrate (1) to a device under test (DUT) (200) that is in contact with the first major surface. The profound benefit of this architecture is its ability to enable a microscopy probe (201) to be positioned in close proximity to the active surface of a DUT (200) while the device remains electrically connected and fully operational. This novel arrangement overcomes the primary deficiency of the prior art, which physically obstructs the DUT, and provides the improved functionality of performing simultaneous, in-situ physical characterization and high-frequency electrical testing.

The functionality of this unique architecture is supported by the characteristics of the planar dielectric substrate (1), which is both cryogenic-compatible and possesses an exceptionally low profile. The substrate (1) may have a profile of less than 400 micrometers and, in some implementations, can be as thin as 5 micrometers. This low profile minimizes the working distance between the microscopy probe (201) and the DUT (200) surface, a critical parameter that enhances the potential resolution and signal fidelity of advanced microscopy techniques. The selection of a cryogenic-compatible material, such as single-crystal silicon, ensures the entire assembly maintains dimensional stability and low-loss dielectric properties during the extreme thermal cycling required for testing superconducting or quantum circuits, thereby providing a more reliable and higher-performing platform.

Electrical signals are routed to the inner contact pads (3) via a plurality of high-speed conductive traces (2). In certain embodiments, these traces (2) are structured as co-planar waveguides, a configuration that effectively confines the electromagnetic fields to minimize signal loss and crosstalk, enabling enhanced performance for signals with frequencies well in excess of 100 GHz. For applications demanding the highest performance, these traces (2) are composed of a superconductive material, such as niobium, which provides nearly lossless signal propagation at cryogenic temperatures. This preserves the integrity of low-power, high-frequency signals with a fidelity that is not achievable using conventional conductive materials, representing a significant improvement in functionality.

A robust and reliable interconnection between the probe card and the DUT (200) is achieved through a multi-faceted compliance system. The plurality of metallic bumps (4), often composed of a malleable material like indium, provides micro-compliance, conforming to the microscopic topography of the DUT's contact pads to ensure a consistent, low-resistance connection. This is complemented, in some embodiments, by a macro-scale compliant region (5) formed by selectively thinning a portion of the substrate (1) proximate to the inner contact pads (3). This engineered flexibility allows for slight, controlled deflection of the contact area. This dual-compliance mechanism ensures that uniform and consistent electrical contact is maintained across the entire array, accommodating minute non-planarity and managing mechanical stresses induced by thermal cycling, thereby ensuring the task of probing is performed more reliably and accurately than with rigid, non-compliant interface structures.

In an embodiment, a method for probing a device under test comprises providing an interface probe card comprising a planar dielectric substrate (1) having a first major surface and an opposing second major surface, a plurality of high-speed conductive traces (2) on the first major surface, a plurality of inner contact pads (3) electrically connected to the plurality of high-speed conductive traces (2) and arranged to define an interior region, a plurality of metallic bumps (4) protruding from the plurality of inner contact pads (3), and an aperture (6) extending entirely through the substrate (1) within the interior region, aligning a device under test (DUT) (200) with the plurality of inner contact pads (3), establishing simultaneous mechanical and electrical communication between the plurality of metallic bumps (4) and a corresponding plurality of contacts on the device under test (DUT) (200), and accessing a surface of the device under test (DUT) (200) with a microscopy probe (201) through the aperture (6) of the interface probe card while the mechanical and electrical communication is maintained. In an embodiment, the method further comprises cooling the interface probe card and the device under test (DUT) (200) to a cryogenic temperature. In an embodiment, the cryogenic temperature is less than 4 Kelvin. In an embodiment, the method further comprises transmitting electrical signals to the device under test (DUT) (200) via the plurality of high-speed conductive traces (2) and the plurality of metallic bumps (4). In an embodiment, the electrical signals have a frequency in excess of 20 GHz. In an embodiment, accessing the surface of the device under test (DUT) (200) comprises performing scanned probe microscopy. In an embodiment, performing the scanned probe microscopy comprises performing scanned SQUID microscopy to characterize magnetic fields emanating from the surface of the device under test (DUT) (200). In an embodiment, the device under test (DUT) (200) is a superconducting digital logic circuit. In an embodiment, the method comprises the simultaneous steps of cooling the interface probe card and the device under test (DUT) (200) to a temperature of less than 4 Kelvin, transmitting electrical signals having a frequency greater than 20 GHz to the device under test (DUT) (200), and performing scanned SQUID microscopy on the surface of the device under test (DUT) (200) by positioning the microscopy probe (201) through the aperture (6). In an embodiment, establishing the simultaneous mechanical and electrical communication comprises creating a semi-permanent die bond between the plurality of metallic bumps (4) and the corresponding plurality of contacts on the device under test (DUT) (200).

The method for probing a device under test (DUT) (200) begins with the step of providing an interface probe card with a specific and novel architecture. This step functions to furnish the essential hardware platform that enables the subsequent, unique analytical operations. The implementation involves supplying the probe card as previously described, having a planar dielectric substrate (1), a plurality of high-speed conductive traces (2) terminating in a plurality of inner contact pads (3) that circumscribe an interior region, a plurality of metallic bumps (4) on the pads (3), and, critically, an aperture (6) passing entirely through the substrate (1) within that interior region. A benefit of initiating the process with this particular apparatus is that its structure provides the foundational utility for reconciling high-bandwidth electrical testing with direct physical access, a non-obvious starting point that improves the functionality of the entire characterization process.

The method proceeds with aligning the device under test (DUT) (200) with the plurality of inner contact pads (3) on the probe card. The function of this step is to achieve precise spatial registration between the contact features of the probe card and the corresponding contact features on the DUT (200). In a typical implementation, this is performed using a high-precision alignment tool, such as a flip-chip die bonder, which allows for micrometer-scale control over the relative positioning. The benefit of this meticulous alignment is the enhanced reliability of the subsequent connection; it ensures a one-to-one correspondence between each metallic bump (4) and its intended DUT contact, thereby performing the task of creating multiple electrical connections more accurately and mitigating the risk of short circuits or open circuits that would render the test invalid.

Following alignment, the method comprises establishing simultaneous mechanical and electrical communication between the plurality of metallic bumps (4) and the corresponding plurality of contacts on the device under test (DUT) (200). This step functions to create an integrated and stable test assembly. It is implemented by applying a controlled force to bring the components into contact, causing the compliant metallic bumps (4) to deform slightly and form a reliable connection. A benefit of this step is the creation of a robust electromechanical fixture where the DUT (200) is both physically secured to and electrically addressable by the probe card. This improved functionality ensures that the connection remains stable and consistent during subsequent handling, temperature cycling, and the introduction of a microscopy probe, which provides for superior durability and measurement integrity. An alternative implementation may involve a temporary pressure contact in a probe station environment rather than a semi-permanent bond.

Finally, the method culminates in accessing a surface of the device under test (DUT) (200) with a microscopy probe (201) through the aperture (6) of the interface probe card while the mechanical and electrical communication is maintained. The function of this step is to perform high-resolution physical analysis on an active, powered device. This is implemented by physically positioning the sensing tip of a microscopy probe (201), such as a SQUID sensor, through the aperture (6) and scanning it across the surface of the DUT (200). The benefit of this step is a new and unique solution to the problem of in-operando characterization. This process provides the practical utility of directly correlating real-time electrical behavior with localized physical phenomena—for instance, observing the formation of magnetic flux vortices in a superconducting circuit as it is driven by a high-frequency signal. This enhanced performance and improved functionality represent a non-obvious method for diagnostics and research that was not possible with prior art methodologies.

In some embodiments, the method includes the additional step of cooling the interface probe card and the device under test (DUT) (200) to a cryogenic temperature. The function of this step is to place the entire test assembly into an operating regime required by certain advanced electronic materials and devices. This is implemented by mounting the bonded probe card and DUT (200) assembly within a cryostat, such as a closed-cycle cryocooler or a dilution refrigerator. A key benefit of this step is the improved functionality it provides, enabling the in-situ analysis of devices, such as superconducting circuits, that are non-operational at room temperature. Further, the cryogenic temperature may be less than 4 Kelvin, a specific range that provides the enhanced performance necessary to test devices fabricated from low-temperature superconductors like niobium, whose unique electrical properties only manifest below this threshold.

The method may further comprise transmitting electrical signals to the device under test (DUT) (200) via the plurality of high-speed conductive traces (2) and the plurality of metallic bumps (4). This step functions to actively drive the DUT (200), allowing its dynamic operational behavior to be characterized. It is implemented by connecting external signal sources to the probe card, thereby stimulating the circuit. The benefit of this step is that it transitions the analysis from a static, structural observation to a dynamic, in-operando measurement, providing a more accurate and useful characterization of the device's real-world performance. In some applications, the electrical signals have a frequency in excess of 20 GHZ, a superior performance metric that demonstrates the method's utility for testing state-of-the-art, high-speed integrated circuits whose operational speeds surpass the capabilities of conventional probing techniques.

The step of accessing the surface of the device under test (DUT) (200) may be further defined as performing scanned probe microscopy. The function of this specific type of access is to acquire highly localized, high-resolution data from the DUT (200) surface. This is implemented by using a scanned probe microscope head as the microscopy probe (201). The benefit of this implementation is the improved accuracy of the physical characterization, allowing for the mapping of surface properties with nanometer-scale precision. In a particularly novel application, performing the scanned probe microscopy comprises performing scanned SQUID microscopy to characterize magnetic fields emanating from the surface of the DUT (200). This provides the unique utility of visualizing and quantifying local magnetic phenomena, such as trapped flux vortices in a superconductor, which offers a non-obvious diagnostic capability critical for debugging and optimizing magnetic memory and superconducting logic devices.

In certain applications, the device under test (DUT) (200) is specifically a superconducting digital logic circuit. This application of the method provides a practical and targeted solution to a significant challenge in the field of advanced computing. The benefit is that the entire process is uniquely suited to address the combined requirements of these specific circuits, namely, cryogenic operation, high-frequency signals, and sensitivity to local magnetic fields, thereby providing an improved functionality that directly enables their research and development. A powerful implementation of the method involves the simultaneous execution of several steps: cooling the assembly to a temperature of less than 4 Kelvin, transmitting electrical signals greater than 20 GHz, and performing scanned SQUID microscopy on the DUT (200) surface. The benefit of this combined process is a synergistic, enhanced performance that provides a complete, in-operando picture of the device's behavior under its precise operational conditions, a task performed more efficiently and with greater insight than any sequence of separate, disconnected measurements.

The step of establishing simultaneous mechanical and electrical communication may be accomplished by creating a semi-permanent die bond between the plurality of metallic bumps (4) and the corresponding plurality of contacts on the device under test (DUT) (200). This is implemented using a flip-chip bonder to apply controlled force, creating a durable metallurgical bond. A primary benefit of this technique is the superior durability and thermal conductivity of the connection compared to a temporary pressure contact, ensuring the interface remains reliable throughout long-duration measurements and repeated thermal cycles.

In an embodiment, a method for fabricating an interface probe card comprises providing a planar dielectric substrate (1) having a first major surface and a second major surface opposite the first major surface, depositing a layer of a conductive material onto the first major surface of the planar dielectric substrate (1), patterning the layer of the conductive material to define a plurality of high-speed conductive traces (2) and a plurality of inner contact pads (3), each of the plurality of inner contact pads (3) electrically connected to at least one of the plurality of high-speed conductive traces (2), wherein the plurality of inner contact pads (3) circumscribe an interior region of the first major surface, depositing a plurality of metallic bumps (4), wherein each metallic bump of the plurality of metallic bumps (4) is deposited onto one of the plurality of inner contact pads (3), and after depositing the plurality of metallic bumps (4), etching entirely through the planar dielectric substrate (1) from the first major surface to the second major surface to form an aperture (6) located within the interior region. In an embodiment, providing the planar dielectric substrate (1) comprises providing a single-crystal silicon wafer. In an embodiment, depositing the layer of the conductive material comprises sputter-depositing a superconductive material. In an embodiment, the superconductive material is niobium. In an embodiment, patterning the layer of the conductive material comprises performing reactive ion etching. In an embodiment, depositing the plurality of metallic bumps (4) comprises depositing indium using a lift-off process. In an embodiment, etching entirely through the planar dielectric substrate (1) comprises performing deep reactive ion etching. In an embodiment, the method further comprises micromachining the outer dimensions of the planar dielectric substrate (1) simultaneously with performing the deep reactive ion etching to form the aperture (6). In an embodiment, the method further comprises etching a portion of the second major surface of the substrate (1) to form a compliant region (5) with a reduced thickness, the compliant region (5) being located proximate to the plurality of inner contact pads (3). In an embodiment, providing the planar dielectric substrate (1) comprises providing a single-crystal silicon wafer, depositing the layer of the conductive material comprises depositing niobium, depositing the plurality of metallic bumps (4) comprises depositing indium, and etching entirely through the planar dielectric substrate (1) comprises performing deep reactive ion etching.

The method for fabricating an interface probe card is a sequence of microfabrication operations that begins with providing a planar dielectric substrate (1). This initial step functions to establish the foundational workpiece, which has a first major surface for component fabrication and an opposing second major surface. The implementation of this step typically involves sourcing a high-quality, low-defect wafer, for instance a single-crystal silicon wafer. A benefit of starting with such a substrate (1) is that it provides a platform of known mechanical rigidity and electrical insulating character, ensuring the dimensional stability and planarity needed for the subsequent high-resolution processing steps, thereby making the overall fabrication process more accurate and reliable.

The method continues with depositing a layer of a conductive material onto the first major surface of the planar dielectric substrate (1). This step functions to apply the raw material from which the card's electrical pathways will be formed. In one implementation, a uniform film of a superconductive metal such as niobium is applied using a physical vapor deposition technique like sputter deposition. The benefit of this step is the creation of a high-purity, uniform conductive layer across the entire surface, which provides for enhanced performance in the final device by enabling the formation of transmission lines with consistent and predictable impedance characteristics, a critical factor for high-frequency operation.

The method then proceeds with patterning the layer of the conductive material. This step's function is to define the specific and intricate geometry of the probe card's circuitry. It is implemented using standard photolithography to transfer a design from a mask to a photoresist layer, followed by an etching process, such as reactive ion etching, to selectively remove the conductive material and thereby define a plurality of high-speed conductive traces (2) and a plurality of inner contact pads (3). Each inner contact pad (3) is electrically connected to at least one of the traces (2), and the pads (3) are arranged to circumscribe an interior region of the first major surface. This process provides the utility of creating a high-density, precision-aligned electrical network in a single, efficient step, while the specific arrangement of the pads (3) to circumscribe an interior region is a novel fabrication feature that structurally delineates the area for the future access path.

Following the circuit definition, the method comprises depositing a plurality of metallic bumps (4), with each metallic bump (4) being deposited onto one of the plurality of inner contact pads (3). This step functions to create the three-dimensional structures necessary for a compliant physical and electrical interface with a separate device. In practice, this may be implemented via a lift-off process, where a thick photoresist is patterned with openings over the pads (3), a soft metal like indium is deposited, and the resist is subsequently dissolved, leaving the metallic bumps (4) behind. A benefit of this step is the improved functionality of the finished probe card; these bumps (4) provide a reliable and compliant interface that can accommodate microscopic surface non-planarity, ensuring uniform electrical contact across a large array of connections.

A culminating step in the method involves, after depositing the plurality of metallic bumps (4), etching entirely through the planar dielectric substrate (1) from the first major surface to the second major surface to form an aperture (6) located within the interior region. The function of this step is to create the through-hole for physical access. Its implementation, for example through deep reactive ion etching, is critically defined by its sequence. The benefit of performing this high-aspect-ratio etch through the full thickness of the substrate (1) after the formation of the sensitive front-side features is a non-obvious and highly impactful manufacturing choice. This sequence provides a more reliable fabrication process by ensuring that the substrate (1) remains a complete, mechanically stable workpiece during all precision alignment, deposition, and patterning steps, which prevents warping or stress-induced damage that could destroy the delicate circuitry. This novel process ordering ensures the structural integrity of the high-speed traces (2) and metallic bumps (4), leading to a higher yield of functional devices and ensuring the final product meets its superior performance specifications.

In some fabrication processes, providing the planar dielectric substrate (1) comprises providing a single-crystal silicon wafer. This selection of a specific material provides a highly uniform and well-characterized starting workpiece, which is a benefit that improves the accuracy and repeatability of the entire fabrication sequence. The established and mature processing techniques available for silicon, particularly for high-fidelity etching, allow for the creation of features with tighter tolerances, performing the task of fabricating the device more reliably than with less common or non-crystalline substrates.

The step of depositing the layer of conductive material may be further specified as sputter-depositing a superconductive material. This implementation functions to create a high-purity, dense, and strongly adherent conductive film. The benefit of using a sputter deposition technique is the enhanced performance of the final conductive traces (2), as the resulting film has excellent uniformity and electrical properties. Directly depositing a superconductive material in this manner is a more efficient method for ensuring the final device possesses the necessary near-lossless conduction properties for cryogenic, high-frequency applications. In certain fabrication processes, the superconductive material is niobium. The utility of selecting niobium is its relatively high superconducting transition temperature (approximately 9.2 K) and its mechanical robustness, which makes it compatible with a wide range of standard cryogenic systems and subsequent fabrication steps, providing for a more durable and versatile final product.

The patterning of the conductive layer may be accomplished by performing reactive ion etching. This implementation functions to selectively remove the conductive material with a high degree of anisotropy. A benefit of using reactive ion etching is the ability to create conductive traces (2) and pads (3) with sharply defined vertical sidewalls and minimal undercutting. This provides for improved functionality by enabling the fabrication of higher-density and higher-precision waveguide geometries, which in turn leads to enhanced performance at very high frequencies.

The step of depositing the plurality of metallic bumps (4) may be implemented by depositing indium using a lift-off process. This specific choice of material and method functions to precisely locate the soft, compliant contact structures only on the inner contact pads (3). The benefit of using a lift-off process is that it is a highly accurate method for patterning materials like indium that are not easily etched. This provides a more reliable manufacturing technique for creating the three-dimensional bumps (4) essential for the probe card's compliant interface.

The formation of the aperture (6) by etching entirely through the planar dielectric substrate (1) may be performed using deep reactive ion etching. This advanced etching technique is uniquely functional for creating high-aspect-ratio features with nearly vertical sidewalls through the full thickness of the substrate (1). A benefit of this implementation is the superior geometric precision of the resulting aperture (6), which is a non-obvious process choice that provides enhanced performance by maximizing the unobstructed access area while maintaining the structural integrity of the surrounding thin substrate walls. The fabrication method may further comprise the step of micromachining the outer dimensions of the planar dielectric substrate (1) simultaneously with performing the deep reactive ion etching to form the aperture (6). This combination of steps provides a significant benefit by performing the overall fabrication task more efficiently, consolidating the aperture formation and the die singulation into a single process, which reduces handling and improves manufacturing throughput.

The fabrication method may also include etching a portion of the second major surface of the substrate (1) to form a compliant region (5) with a reduced thickness, the compliant region (5) being located proximate to the plurality of inner contact pads (3). The function of this additional step is to engineer localized flexibility into the substrate (1) itself. The benefit is an improved functionality in the final device, where this compliant region (5) allows for controlled deflection during contact with a DUT, ensuring more uniform contact pressure across the array of metallic bumps (4) and making the probing process more reliable.

In a particular embodiment, the method combines several specific process choices, wherein providing the planar dielectric substrate (1) comprises providing a single-crystal silicon wafer, depositing the layer of the conductive material comprises depositing niobium, depositing the plurality of metallic bumps (4) comprises depositing indium, and etching entirely through the planar dielectric substrate (1) comprises performing deep reactive ion etching. This specific sequence and combination of materials and processes provides a novel and non-obvious fabrication flow that synergistically leverages the benefits of each step to produce an interface probe card with superior durability, reliability, and enhanced performance metrics for the most demanding test and measurement applications.

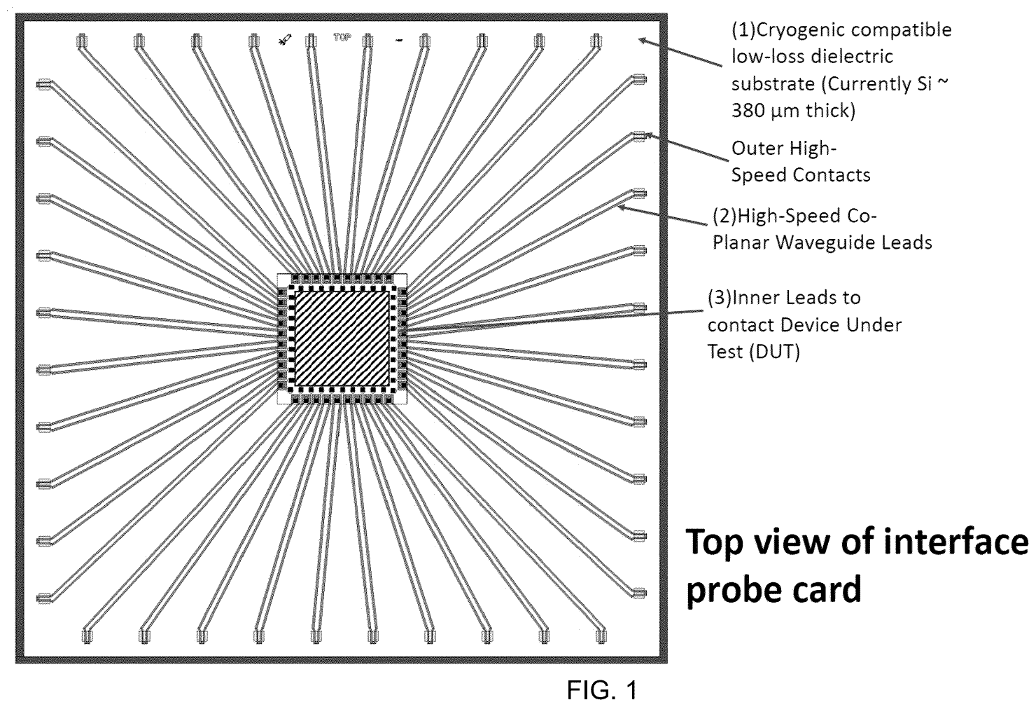

FIG. 1 provides a top-down schematic illustration of an interface probe card according to one embodiment. The apparatus is constructed upon a planar dielectric substrate (1), which forms the foundational mechanical and electrical support structure for the entire assembly. This planar dielectric substrate (1) is the continuous body, represented by the purple perimeter in FIG. 1, upon which all other components are disposed. The material selected for the substrate (1) is a cryogenic-compatible, low-loss dielectric, with a principal implementation being a single-crystal silicon wafer. The thickness of the planar dielectric substrate (1) provides the structural rigidity of the card and can be from 5 micrometers to 1000 micrometers, specifically from 50 micrometers to 500 micrometers, and more specifically around 380 micrometers. The use of a material like silicon offers the benefit of exceptional dimensional stability and minimal dielectric loss, particularly at cryogenic temperatures and across a wide frequency spectrum, ensuring the structural and electrical integrity of the device under extreme operating conditions. This improved functionality allows the probe card to be reliably used in demanding environments for testing superconducting and quantum circuits. Variations of the substrate (1) may include other suitable low-loss dielectric materials such as sapphire or high-purity quartz.

A plurality of high-speed co-planar waveguide leads (2), also referred to as high-speed conductive traces, are disposed upon the first major surface of the planar dielectric substrate (1). These traces (2) are depicted in FIG. 1 as the plurality of lines radiating from the region of the substrate (1) to its outer periphery. The primary function of these high-speed conductive traces (2) is to serve as high-fidelity transmission lines, routing electrical signals between external test instrumentation and the device under test. They are electrically connected to outer high-speed contacts at the periphery of the substrate (1), which serve as the interface points to external cabling or equipment. The implementation of these traces (2) as co-planar waveguides, where a signal conductor is flanked by ground planes on the same surface, provides the benefit of excellent electromagnetic field confinement. This enhanced performance minimizes signal loss, dispersion, and crosstalk between adjacent channels, enabling the transmission of signals with a bandwidth that can be from 1 GHz to 200 GHz, specifically from 10 GHz to 150 GHz, and more specifically in excess of 100 GHz. For certain applications, these traces (2) are fabricated from a superconductive material, such as niobium, to achieve nearly lossless signal propagation at cryogenic temperatures, a practical application that is highly advantageous for low-power and high-sensitivity measurements. The number of high-speed conductive traces (2) can be varied to suit the specific input/output requirements of the device under test; FIG. 1 illustrates an embodiment with forty such traces.

The high-speed conductive traces (2) terminate at their inner ends at a corresponding plurality of inner contact pads (3). The illustration in FIG. 1 shows these inner contact pads (3) arranged in a dense, geometric pattern, specifically a square perimeter array, that circumscribes an interior region, which is depicted as a hatched area. The function of these inner contact pads (3) is to act as the final terminal points on the probe card for establishing electrical communication with a device under test. This arrangement provides the novel utility of consolidating a high-density electrical interface into a compact footprint while simultaneously delineating a, protected zone. The benefit of this specific geometric configuration is that it physically creates the boundary for the aperture (6), thereby enabling the core functionality of unobstructed physical and optical access to the device under test. The hatched area represents the location where a device under test (DUT) would be bonded and corresponds to the position of the aperture (6) that extends through the substrate (1). This structure provides the non-obvious solution of integrating a high-performance electrical interface with a direct, line-of-sight access path for in-situ microscopy, an improved functionality that is not present in conventional probe card designs.

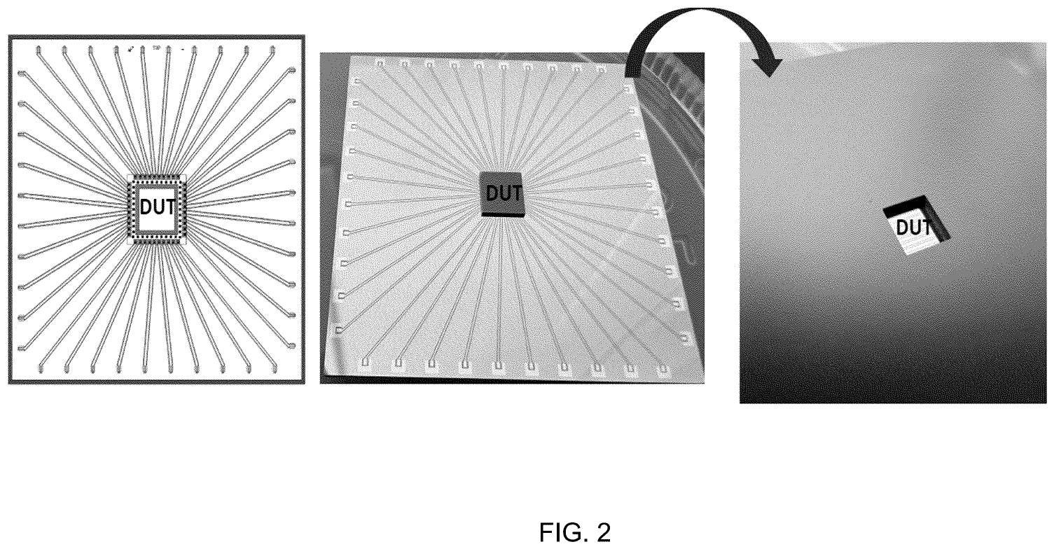

FIG. 2 presents a composite view that illustrates the progression from a design schematic to a physically realized and assembled interface probe card, highlighting the core structural features and their functional implementation. The leftmost panel of FIG. 2 displays a top-down design drawing, similar to that shown in FIG. 1, which serves as the blueprint for the apparatus; this schematic explicitly shows the intended placement of a device under test (DUT) (200) within the interior region defined by the geometric pattern of the inner contact pads (3). The high-speed conductive traces (2) are shown radiating outward from this interface zone, establishing the fundamental design principle of peripheral electrical routing to create an unobstructed area. This design visualizes the interconnectivity where the DUT (200) is positioned to receive electrical signals from the surrounding traces (2).

The middle panel of FIG. 2 transitions from the abstract design to a tangible embodiment, showing a photograph of a fully fabricated interface probe card after a device under test (DUT) (200) has been physically bonded to its first major surface. This image demonstrates the practical implementation of the design, where a distinct microelectronic chip, the DUT (200), is precisely aligned and mounted onto the planar dielectric substrate (1). The visible high-speed conductive traces (2) on the substrate (1) are shown terminating at the periphery of the bonded DUT (200). The physical structure demonstrates the successful establishment of simultaneous mechanical and electrical communication, a process effectuated by the plurality of metallic bumps (4) located between the probe card's inner contact pads (3) and the corresponding contacts on the DUT (200). This bonded assembly represents a functional unit ready for testing and analysis, showcasing the durability of the electromechanical connection. The operability shown here is the creation of a stable, integrated test structure.

The rightmost panel of FIG. 2 reveals the most novel and non-obvious aspect of the apparatus, providing a perspective view of the second major surface, or backside, of the wafer containing the assembled probe card. This view clearly shows the aperture (6), which has been etched entirely through the planar dielectric substrate (1). The critical feature demonstrated in this panel is the direct, unobstructed visibility of the device under test (DUT) (200) through this aperture (6). The curved arrow linking the middle and right panels signifies that the right panel is a view of the reverse side of the assembly shown in the middle panel. This physical structure provides the unique utility of exposing the active surface of the DUT (200) for analysis from the side opposite its electrical interconnections. The benefit of this configuration is an unprecedented level of access, providing an improved functionality that fundamentally overcomes the physical obstruction limitations inherent in all prior art probe card designs. This unobstructed line-of-sight path enables the use of various microscopy probes (201) to be brought into close proximity with the DUT (200) surface for in-situ characterization while the device is actively powered and operating. The dimensions of the aperture (6) can be tailored to the specific microscopy technique and can be from 1 millimeter to 20 millimeters on a side, specifically from 2 millimeters to 10 millimeters, and more specifically around 4.5 millimeters, providing a sufficiently large opening for a variety of physical probes. The combination of views in FIG. 2 therefore demonstrates a complete system, from design to a final, functional assembly, that provides a new and unique solution for performing advanced, in-operando metrology on high-performance microelectronic devices. This method of concurrent analysis performs the task of device characterization more efficiently, accurately, and with greater insight than previously possible.

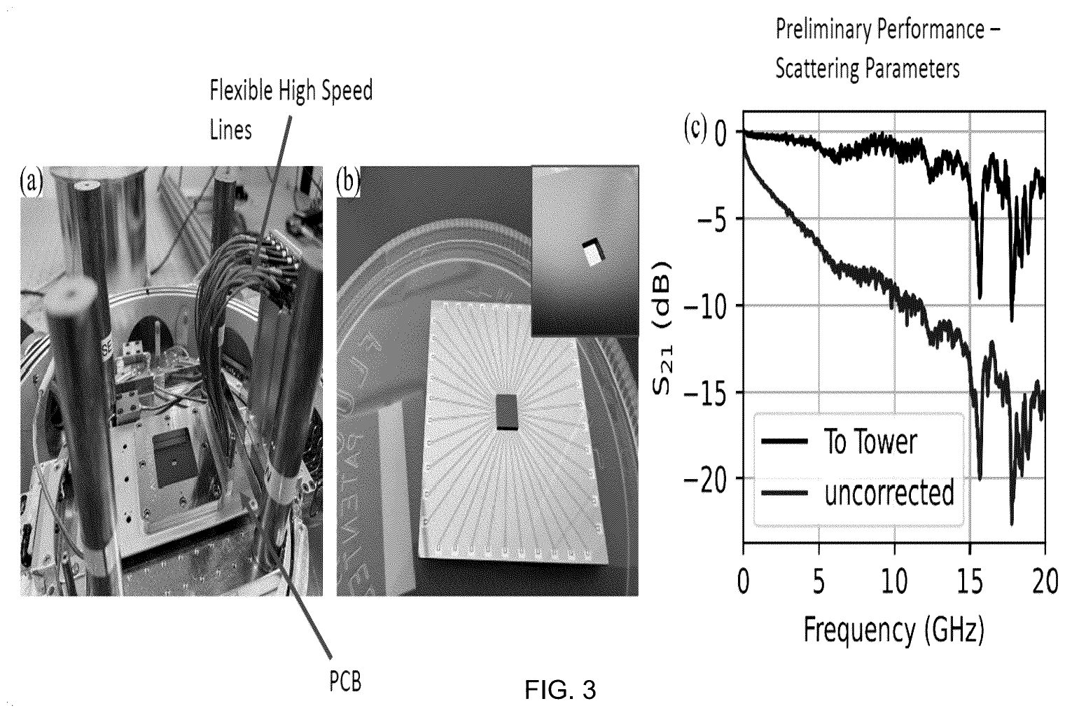

FIG. 3 is a composite figure that provides views of a physical implementation of the interface probe card within a test environment, alongside preliminary data characterizing its high-frequency electrical performance. Panel (a) of FIG. 3 shows a photograph of an assembled interface probe card, having a device under test (DUT) (200) bonded to it, mounted within a cryogenic test fixture. This implementation demonstrates the practical utility of the apparatus in a complex measurement system. The probe card is shown secured within a holder, which is in turn connected to a printed circuit board (PCB). A bundle of flexible high-speed lines provides the electrical interconnectivity between the outer contacts of the probe card and the larger test system infrastructure, routing signals to and from the DUT (200). The assembly is surrounded by copper thermal posts, illustrating its integration into an environment designed for cryogenic operation. The physical structure shown in panel (a) provides an example of use where the probe card serves as the critical interface in a low-temperature, high-frequency probe station.

Panel (b) of FIG. 3 shows a photograph of the fabricated probe card with the bonded DUT (200), similar to the view in FIG. 2, further illustrating the successful realization of the design. An inset within panel (b), highlighted by a red border, provides a crucial view of the second major surface of the apparatus, clearly showing the DUT (200) as it is visible through the aperture (6) etched entirely through the planar dielectric substrate (1). This view physically substantiates the novel design's ability to provide an unobstructed line-of-sight path to the DUT (200), a benefit that enables the improved functionality of in-situ microscopy. The operability demonstrated is that of a complete, bonded assembly where the access path is maintained.

Panel (c) of FIG. 3 presents a graph of preliminary scattering parameter data, which provides objective evidence of the high-frequency performance of the interface probe card. The graph plots the forward transmission coefficient, S21, measured in decibels (dB), as a function of signal frequency, measured in gigahertz (GHz). The S21 parameter quantifies the signal loss, or insertion loss, through the signal path. The black trace, labeled “To Tower,” represents a reference measurement of the signal path leading up to the probe card, showing very low loss across the measured frequency range. The blue trace, labeled “uncorrected,” represents the measured transmission through the entire signal path including the flexible high-speed lines, the PCB, and the interface probe card itself. This data demonstrates the enhanced performance of the probe card's architecture, which is capable of transmitting high-frequency signals with manageable attenuation. The functional bandwidth of the apparatus shown in the data can be from DC to 100 GHz, specifically from DC to 40 GHZ, and more specifically from DC to at least 20 GHz. The measured loss, even in this uncorrected state, is less than 15 dB at 20 GHz. This superior performance metric is a direct consequence of the careful implementation of the high-speed conductive traces (2) as co-planar waveguides on the low-loss planar dielectric substrate (1). The ability to maintain signal integrity at such high frequencies is a practical application that makes the probe card suitable for characterizing next-generation digital and mixed-signal integrated circuits, performing this task more accurately than conventional interfaces with higher insertion loss.

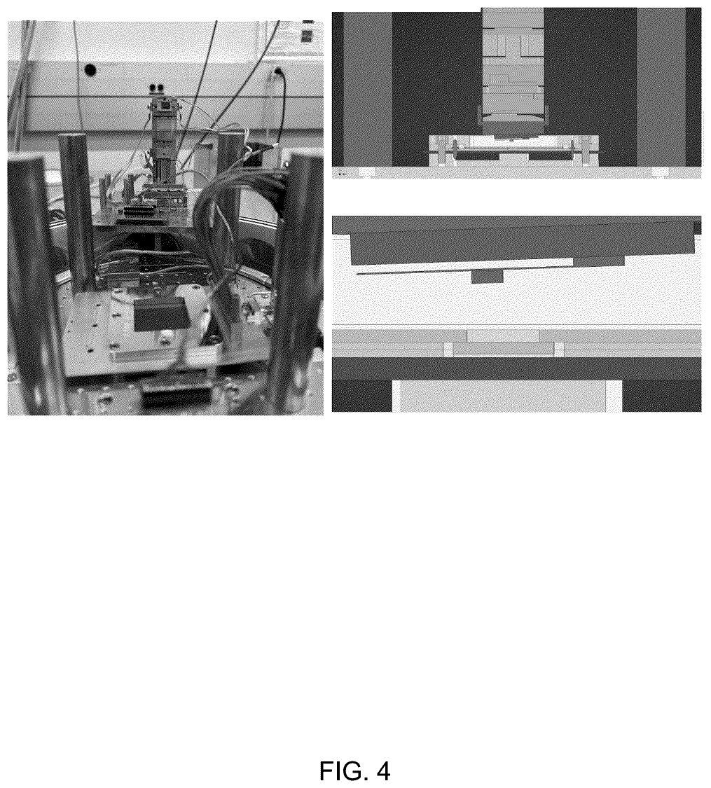

FIG. 4 presents a series of illustrations that provide a concrete example of use for the interface probe card, demonstrating its integration and operability within a scanned SQUID microscope system, which is a practical application that highlights the unique benefits of the invention's architecture. The leftmost panel of FIG. 4 is a photograph of a physical implementation, showing the interface probe card assembly mounted within the cryogenic sample space of the microscope. This view shows a microscopy probe (201), embodied as a SQUID sensor assembly, positioned vertically above the interface probe card, which holds a device under test (DUT) (200). The interconnectivity of the system is also visible, with flexible high-speed lines and a printed circuit board providing the electrical pathways to the probe card. The entire apparatus is situated within a framework of copper posts designed for thermal management, underscoring its implementation in a low-temperature environment. This physical setup demonstrates the utility of the probe card as a functional component in a complex, state-of-the-art metrology instrument.

The upper right panel of FIG. 4 provides a schematic side cross-sectional view of the interaction between the microscopy probe (201) and the interface probe card assembly. This illustration clarifies the physical structure and spatial relationship of the components. The microscopy probe (201) is shown vertically aligned with, and in close proximity to, the interface probe card, which comprises the planar dielectric substrate (1) and the bonded device under test (DUT) (200). The operability demonstrated here is the ability to bring the sensing element of the microscopy probe (201) extremely close to the surface of the DUT (200). A primary benefit of the interface probe card's low-profile design is the significant reduction in the achievable working distance between the probe and the sample. This working distance can be from 1 millimeter to 1 micrometer, specifically from 200 micrometers to 5 micrometers, and more specifically on the order of 10 micrometers. This enhanced performance directly translates to improved functionality in the microscopy measurement, enabling higher spatial resolution and a superior signal-to-noise ratio.

The lower right panel of FIG. 4 offers a magnified, detailed schematic cross-section of the critical interface region. This view provides a clear depiction of the novel method of access. The microscopy probe (201) is shown accessing the top surface of the device under test (DUT) (200). This access is made possible by the aperture (6) that extends entirely through the planar dielectric substrate (1). The DUT (200) is shown bonded to the opposite side of the substrate (1), with the electrical connection being made via the plurality of metallic bumps (4) and inner contact pads (3), which are located on the first major surface of the substrate (1). This structure functionally decouples the physical access path from the electrical signal paths. The benefit of this arrangement is a new and unique solution that completely eliminates the physical obstruction that plagues conventional probe card designs. The improved functionality allows for direct, in-situ analysis of the DUT's (200) active surface while it is simultaneously powered and interrogated with high-frequency electrical signals. The combination of the photograph and the schematic diagrams in FIG. 4 thus provides a comprehensive illustration of the invention's practical utility, showing how its non-obvious architecture enables a new paradigm of in-operando testing, thereby performing the task of device characterization more efficiently, accurately, and with a level of insight that was previously unattainable.

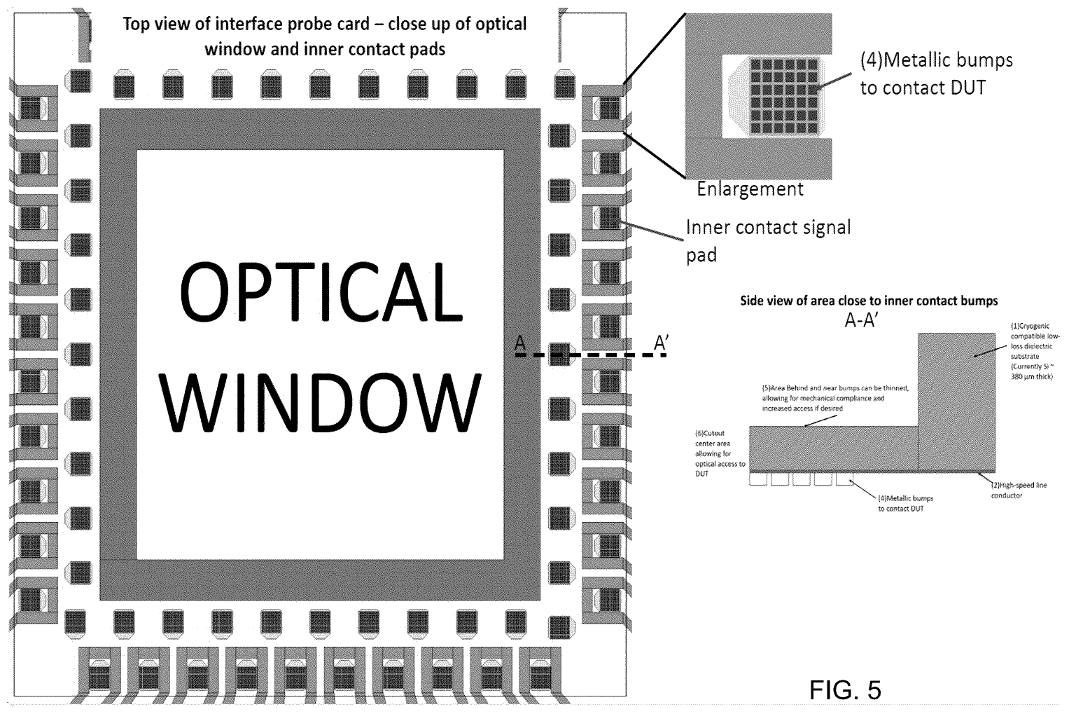

FIG. 5 provides a series of detailed schematic views of the interface region of the interface probe card, illustrating the specific physical structure and arrangement of the key components that enable its unique functionality. The main view on the left is a top-down schematic that focuses on the geometric layout of the area. This view shows the aperture (6), labeled as an “OPTICAL WINDOW,” which forms the unobstructed physical and optical pathway through the apparatus. This aperture (6) is peripherally surrounded by a geometric pattern of inner contact pads (3), which are implemented as a dense perimeter array. The interconnectivity of the system is shown by the high-speed conductive traces (2) that terminate at each of the inner contact pads (3). The operability of this layout is to spatially segregate the electrical interface from the physical access path, a novel structural arrangement that provides the benefit of allowing a microscopy probe (201) to access a device under test (DUT) (200) without any physical obstruction from the probe card's own circuitry.

An enlarged view in the upper right quadrant of FIG. 5 provides a detailed look at a single inner contact signal pad, which is a component of the plurality of inner contact pads (3). This view illustrates the physical structure used to make the final electrical connection to a DUT (200). On the surface of the pad, a plurality of metallic bumps (4) are disposed, shown here as a grid-like array. The function of these metallic bumps (4) is to serve as three-dimensional, protuberant contact points. In one implementation, these are formed from a soft, malleable metal such as indium. The benefit of this structure is the creation of a compliant and reliable electrical interface; the plurality of small bumps (4) can accommodate microscopic surface non-planarity on the DUT (200), ensuring a uniform, low-resistance connection is established, which improves the accuracy and reliability of the electrical measurements.

A side cross-sectional view, taken along the line A-A′ of the main top-down view, is provided in the lower right quadrant of FIG. 5. This diagram illustrates the vertical structure of the interface probe card in the immediate vicinity of the inner contact pads (3). The main body of the apparatus is the planar dielectric substrate (1), noted in this embodiment as a cryogenic-compatible, low-loss silicon wafer with a thickness of approximately 380 micrometers. On the first major surface of the substrate (1), a high-speed line conductor, which is part of the high-speed conductive traces (2), is disposed. The plurality of metallic bumps (4) are shown protruding from this conductor, positioned to make contact with a DUT (200). The cross-section clearly shows the cutout area, which constitutes the aperture (6), extending entirely through the substrate (1). The functionality of this through-hole is to provide a direct, unobstructed path for a microscopy probe (201), a new and unique solution for in-operando device analysis.

The cross-sectional view in FIG. 5 also reveals an alternative embodiment incorporating a compliant region (5). This region is implemented as a thinned area of the planar dielectric substrate (1) located behind and proximate to the metallic bumps (4). The physical structure is a recess etched into the substrate (1), reducing its local thickness. The thickness of this compliant region (5) can be from 1 micrometer to 200 micrometers, specifically from 5 micrometers to 100 micrometers, and more specifically from 10 micrometers to 50 micrometers. The function of this compliant region (5) is to introduce localized mechanical flexibility into the otherwise rigid substrate (1). The benefit of this non-obvious design feature is improved functionality during the bonding process; the engineered compliance allows the contact area to deflect slightly when pressed against a DUT (200). This deflection enables a slight overdriving of the contact, ensuring that uniform pressure is applied across the entire array of metallic bumps (4), which provides for a more robust and reliable electrical connection, especially for large-area devices or in the presence of minor non-planarity. This enhanced performance makes the overall task of probing a device more reliable and less susceptible to failure from intermittent contacts. The compliant region (5) also provides the benefit of potentially increased physical access for certain angled microscopy techniques, further enhancing the utility of the apparatus.

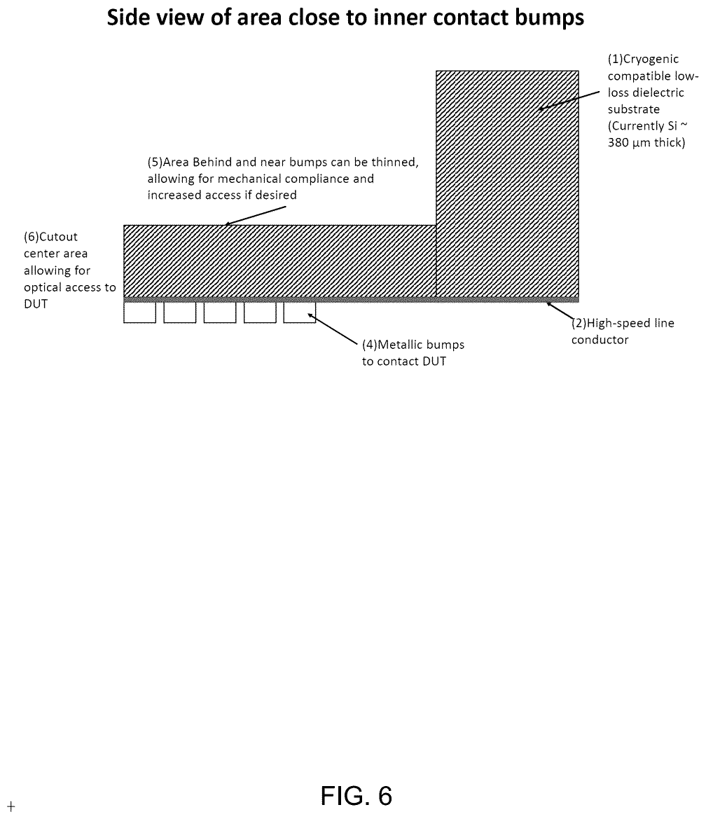

FIG. 6 presents a detailed schematic side cross-sectional view of the interface probe card, focusing on the vertical architecture in an area proximate to the inner contact bumps and illustrating the structural features that provide both mechanical compliance and physical access. This view elucidates the non-obvious structural relationships that afford the apparatus its unique operational advantages. The main structural body is the planar dielectric substrate (1), which is shown with a stepped profile in this region and is composed of a cryogenic-compatible, low-loss material. An exemplary implementation utilizes single-crystal silicon for the substrate (1), with a nominal thickness that can be from 5 micrometers to 1000 micrometers, specifically from 50 micrometers to 500 micrometers, and more specifically around 380 micrometers in the thicker, un-etched portions. The substrate (1) provides the essential mechanical support and electrical isolation for the active components of the probe card.

Disposed on the first major surface, which is the lower surface in this orientation, is a high-speed line conductor (2). This conductor (2) represents the terminal portion of a high-speed conductive trace and serves as the electrical pathway for signals directed to or from a device under test (DUT) (200). The conductor (2) provides the foundational layer upon which the final contact structures are built. Extending downward from the high-speed line conductor (2) is a plurality of metallic bumps (4). The physical structure of these bumps (4) is that of three-dimensional protrusions, which function as the ultimate physical and electrical interface points for making contact with the corresponding pads on a DUT (200). The implementation of these bumps (4) with a compliant material like indium ensures a reliable, low-resistance connection is formed across the entire interface, accommodating microscopic surface irregularities and enhancing the accuracy of the electrical measurements.

A significant feature illustrated in FIG. 6 is the compliant region (5), which is an area of the planar dielectric substrate (1) that has been intentionally thinned. This region (5) is implemented as a recess etched into the substrate (1) from its second major surface, located directly behind and near the array of metallic bumps (4). The functionality of this compliant region (5) is to introduce a controlled, localized mechanical flexibility into the otherwise rigid substrate (1). This non-obvious design provides a substantial benefit by creating an engineered deflection zone. The thickness of this thinned compliant region (5) can be from 1 micrometer to 200 micrometers, specifically from 5 micrometers to 100 micrometers, and more specifically from 10 micrometers to 50 micrometers. This improved functionality allows the contact area of the probe card to be slightly overdriven during the bonding process without imparting excessive or non-uniform force, which could damage the delicate DUT (200). This provides for enhanced performance by ensuring a more uniform pressure distribution across all metallic bumps (4), which is a superior method for achieving a reliable, multi-point connection, particularly for large-area devices or in cryogenic environments where differential thermal contraction can introduce significant mechanical stress. The utility of this feature is a more durable and reliable test fixture.

Adjacent to the compliant region (5) is the cutout area (6), which represents the edge of the aperture that extends entirely through the substrate (1). The function of this aperture (6) is to provide an unobstructed, direct line-of-sight path for physical and optical access to the DUT (200). The physical structure, being a complete void through the substrate, is a new and unique solution to the problem of physical obstruction in prior art probe cards. The implementation shown in FIG. 6, where the compliant region (5) forms a thinned shelf adjacent to this aperture (6), further provides the benefit of potentially increased physical access for microscopy probes (201) that may approach the DUT (200) at an angle. The synergistic combination of the compliant region (5) and the aperture (6) represents a non-obvious structural innovation, where the feature that ensures a reliable electrical connection also enhances the physical access for microscopy. This arrangement performs the task of in-operando device characterization more efficiently and with greater capability than was previously possible.

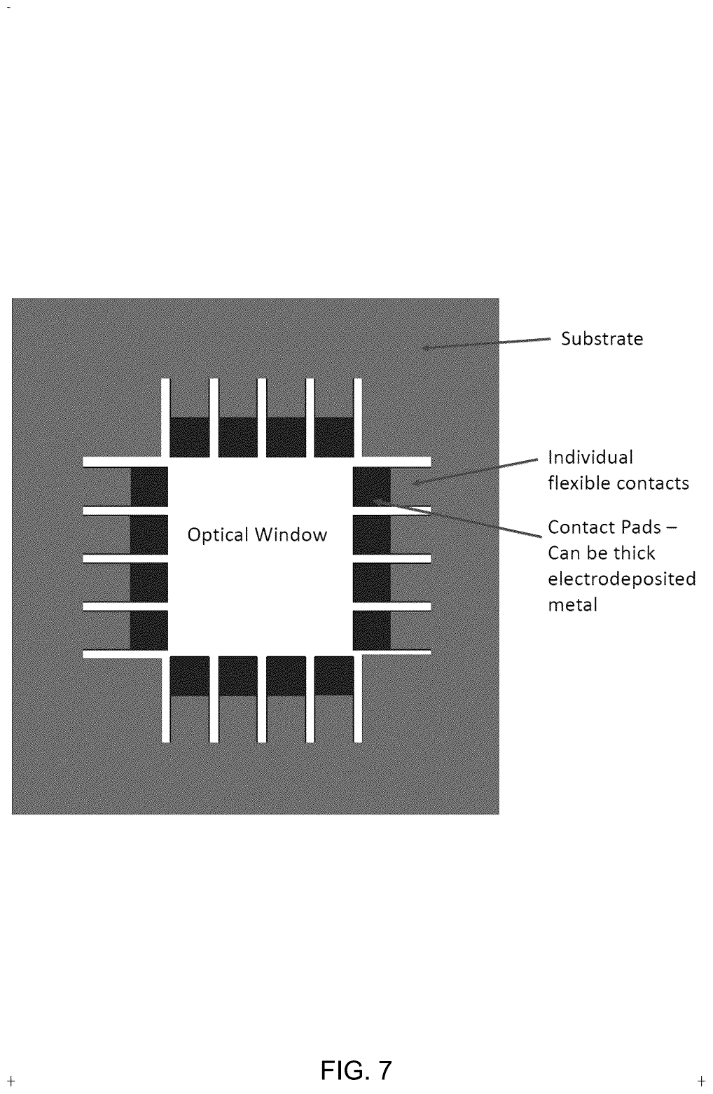

FIG. 7 illustrates a top-down schematic view of an alternative implementation of the interface probe card, which provides a different mechanism for achieving a compliant electrical interface while preserving the core novelty of unobstructed physical access. This embodiment is particularly well-suited for applications requiring temporary, repeatable contact with a device under test (DUT) (200), such as in a conventional probe station environment. The physical structure is based upon a planar dielectric substrate (1), represented as the main body of the apparatus, which provides the mechanical foundation for the other components. Located within this substrate (1) is the aperture (6), labeled in FIG. 7 as the “Optical Window.” This aperture (6) functions identically to that in the previously described embodiments, extending entirely through the substrate (1) to create a direct, unmediated line-of-sight path to a DUT (200) positioned for testing, a benefit that provides the unique utility of in-operando microscopy.

This alternative implementation diverges in its method of providing mechanical compliance and electrical contact. Instead of utilizing soft metallic bumps on a continuous surface, this embodiment incorporates a plurality of individual micromachined flexures (202), labeled as “Individual flexible contacts.” The physical structure of each micromachined flexure (202) is that of a cantilevered beam, micromachined directly from the material of the planar dielectric substrate (1). These flexures (202) are arranged in a geometric perimeter array, projecting inward from the main body of the substrate (1) and peripherally surrounding the aperture (6). The implementation of these distinct, separated flexures (202) is achieved through high-precision micromachining techniques, such as deep reactive ion etching, which defines their shape and releases them to move independently. The length of these flexures (202) can be from 10 micrometers to 500 micrometers, specifically from 20 micrometers to 200 micrometers, and more specifically from 50 micrometers to 150 micrometers.

The operability of this design is fundamentally different; each micromachined flexure (202) provides independent z-axis compliance. This functionality means that when the probe card is brought into contact with a DUT (200), each contact point can deflect vertically, independently of its neighbors. This provides the significant benefit of improved functionality when probing DUTs (200) that may have significant surface topography or non-planarity. This non-obvious solution ensures that a reliable electrical connection can be established at every contact point, as a high point on the DUT (200) will not prevent other, lower points from making contact, thereby performing the task of multi-point probing more reliably and accurately.

At the terminus of each individual micromachined flexure (202) is a hard metal contact pad (203), labeled in FIG. 7 as “Contact Pads.” The physical structure of these pads (203) is a robust, wear-resistant metallic deposit. In one implementation, these hard metal contact pads (203) are formed using a thick electrodeposition process to build up a layer of a hard metal, such as rhodium, tungsten, or a specialized hard gold alloy. The thickness of these pads (203) can be from 1 micrometer to 50 micrometers, specifically from 2 micrometers to 25 micrometers, and more specifically from 5 micrometers to 15 micrometers. The function of using a hard metal is to provide superior durability, a benefit that allows the probe card to withstand many thousands of contact cycles without significant wear or degradation. This enhanced performance makes the apparatus highly suitable for automated, high-volume testing environments. A further benefit is that the hard metal tip can effectively “scrub” through native oxide layers that may be present on the DUT's (200) contact pads, ensuring a low-resistance electrical connection is reliably formed upon contact. This alternative implementation, therefore, provides a new and unique solution for applications where temporary, repeatable, and durable probing is required, while still offering the same unprecedented, unobstructed access for simultaneous in-situ microscopy.

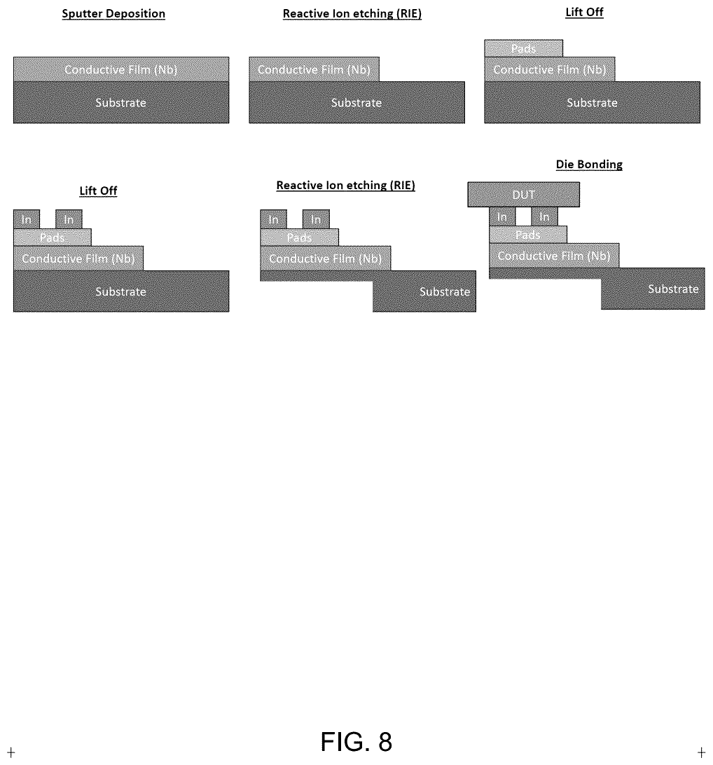

FIG. 8 provides a schematic flowchart that illustrates a simplified, exemplary sequence of microfabrication process steps for manufacturing the interface probe card, with each panel depicting a cross-sectional view of the device at a different stage of fabrication. This sequence of operations represents a novel and non-obvious method for creating the unique physical structure of the apparatus. The process begins with a Sputter Deposition step, as shown in the upper leftmost panel. In this initial operation, a layer of a conductive material (204), such as a superconductive film of Niobium (Nb), is uniformly deposited onto the first major surface of a planar dielectric substrate (1). The implementation of this step by sputtering provides a high-quality, dense, and adherent film, which is a benefit that ensures superior and consistent electrical properties for the conductive features that will be subsequently patterned from this layer. The provision of a uniform film is a critical foundation for achieving the enhanced performance of high-frequency signal transmission in the final device.

The process then proceeds to a Reactive lon Etching (RIE) step, illustrated in the upper middle panel. This step functions to selectively remove portions of the conductive film (204) to define the specific geometry of the probe card's circuitry. A photolithographic mask is used to protect the desired areas, and the exposed conductive material is etched away, leaving behind the patterned high-speed conductive traces (2) and inner contact pads (3) on the substrate (1). The use of an anisotropic etching technique like RIE provides the benefit of creating features with sharp, vertical sidewalls, which improves the functionality of the device by allowing for the fabrication of high-density, high-precision waveguide structures necessary for reliable operation at frequencies in excess of 100 GHz. This performs the task of circuit definition more accurately than isotropic wet etch processes.

Following the definition of the main conductive pathways, a Lift Off process is performed, as shown in the upper rightmost panel. This step is implemented to deposit a secondary layer of material, labeled “Pads” (205), onto specific locations, typically atop the previously formed conductive traces (2) and pads (3). The function of this pads layer (205) is often to provide an improved surface for subsequent bonding, acting as an adhesion layer or a diffusion barrier. The implementation via a lift-off technique provides a more efficient method for precisely patterning this secondary layer, ensuring it is located only where needed, which is a benefit that improves the reliability of the overall structure.

A second Lift Off process is then employed, as illustrated in the lower leftmost panel, to create the three-dimensional contact structures. In this step, the plurality of metallic bumps (4), noted in the figure as Indium (In), are deposited onto the pads layer (205). The function of this step is to build the protuberant, compliant features that will form the final electrical and mechanical interface with a device under test (DUT) (200). Using a lift-off process is a highly reliable method for accurately patterning soft, malleable metals like indium that are not amenable to conventional etching techniques. This provides the utility of creating a robust and compliant interface, a critical element for the improved functionality of the finished probe card.

The next step, shown in the lower middle panel, is a second Reactive lon Etching (RIE) step. This is a critical and non-obvious operation in the fabrication sequence. The function of this step is to form the aperture (6) by etching entirely through the full thickness of the planar dielectric substrate (1). This is typically performed using a deep reactive ion etching (DRIE) process from the second major surface of the substrate (1). The crucial benefit of performing this through-wafer etch after all of the front-side metallization and bump deposition steps have been completed is that it preserves the full mechanical integrity of the substrate (1) during the high-precision front-side processing. This novel sequence provides a more reliable manufacturing process, preventing wafer warping, stress fractures, or misalignment of the delicate conductive features that could occur if the aperture were formed earlier. This leads to a higher yield of functional devices and ensures the final product meets its superior performance specifications.

The final step illustrated in FIG. 8 is Die Bonding, shown in the lower rightmost panel. This step functions to complete the assembly by integrating the fabricated interface probe card with a device under test (DUT) (200). This is implemented by aligning the DUT (200) with the probe card and applying controlled pressure, establishing simultaneous mechanical and electrical communication between the DUT's contacts and the metallic bumps (4) on the probe card. The physical structure shown is the final, operational assembly, where the DUT (200) is electrically connected and its active surface is accessible through the aperture (6). This demonstrates the practical application of the fabrication process in creating a complete test fixture with unprecedented capabilities for in-operando analysis.

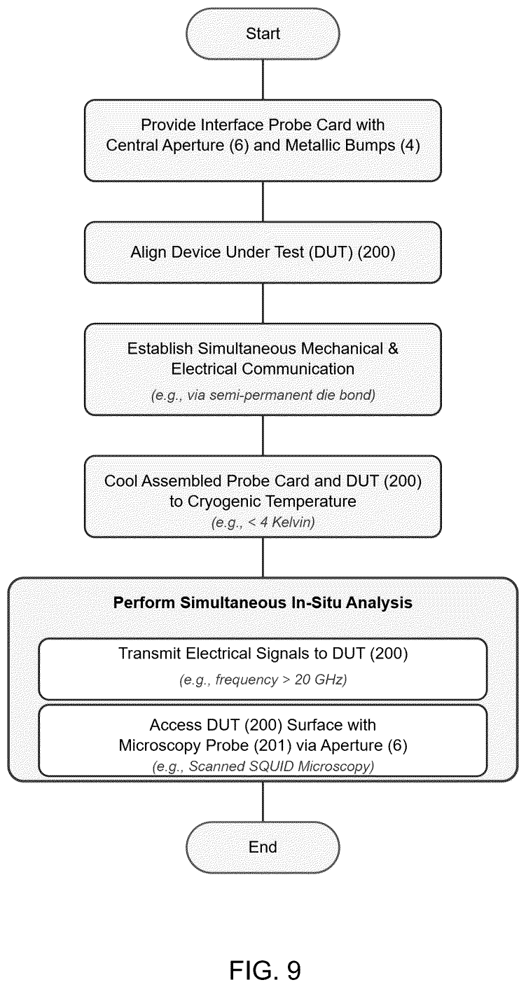

FIG. 9 is a flowchart that illustrates a method for probing a device under test, detailing the sequence of operations that leverage the unique structural characteristics of the interface probe card to enable in-operando analysis. The process commences at a start block and proceeds sequentially through a series of steps designed to prepare and analyze a device under test (DUT) (200) under specific, controlled conditions. The initial operation involves providing the interface probe card, a step which furnishes the specialized hardware platform, including its defining features of an aperture (6) and a plurality of metallic bumps (4). The provision of this particular apparatus is the foundational step upon which the entire novel method is built, as its architecture is what enables the subsequent integration of physical access with electrical probing.

Following the provision of the probe card, the method proceeds to the alignment of a device under test (DUT) (200) with the probe card's contact structures. This operation functions to achieve precise micrometer-scale spatial registration between the metallic bumps (4) on the probe card and the corresponding contact pads on the DUT (200). The successful implementation of this step is a critical precursor to the next, as it ensures a correct one-to-one mapping for the electrical connections, a benefit that improves the accuracy of the entire test by preventing short circuits or open connections that would corrupt the measurement data.

Once alignment is complete, the method involves establishing simultaneous mechanical and electrical communication between the probe card and the DUT (200). This step is implemented by bringing the two components into physical contact, often through a controlled die-bonding process that creates a semi-permanent bond, thereby forming a stable and robust integrated assembly. The functionality of this step is to create a secure electromechanical fixture that maintains a reliable, low-resistance electrical connection throughout the subsequent, often physically demanding, stages of the analysis. A primary benefit is the superior durability of the connection, which can withstand the mechanical stresses of thermal cycling and the physical proximity of a scanning microscopy probe.

The process then continues with the step of cooling the assembled probe card and DUT (200) to a cryogenic temperature. This is a practical application for the analysis of advanced devices, such as superconducting circuits, that are only functional in a low-temperature environment. The implementation involves placing the entire assembly into a cryostat. The temperature can be reduced to a general cryogenic range or, for specific applications requiring the characterization of low-temperature superconductors, to a temperature below 4 Kelvin. The benefit of this step is the improved functionality of enabling tests under the precise environmental conditions required for the device's operation, providing for a more accurate and relevant characterization of its performance.

The culmination of the method is the step of performing simultaneous in-situ analysis, a complex operation that comprises two concurrent sub-processes. The first sub-process is the transmission of electrical signals to the DUT (200), which may include high-frequency signals with a frequency in excess of 20 GHZ. This actively stimulates the device, allowing for the characterization of its dynamic behavior. Concurrently, the second sub-process involves accessing the DUT (200) surface with a microscopy probe (201) by positioning the probe through the aperture (6). A specific example of this is the use of a scanned SQUID microscope to map local magnetic fields. The primary benefit of this combined, simultaneous analysis is a novel and non-obvious solution to the long-standing problem of in-operando metrology. This improved functionality provides the unique utility of directly correlating, in real-time, the device's high-frequency electrical response with its localized physical properties, a task that can be performed more efficiently and with far greater insight than any series of separate, disconnected measurements. The process concludes at an end block after the analysis is complete.

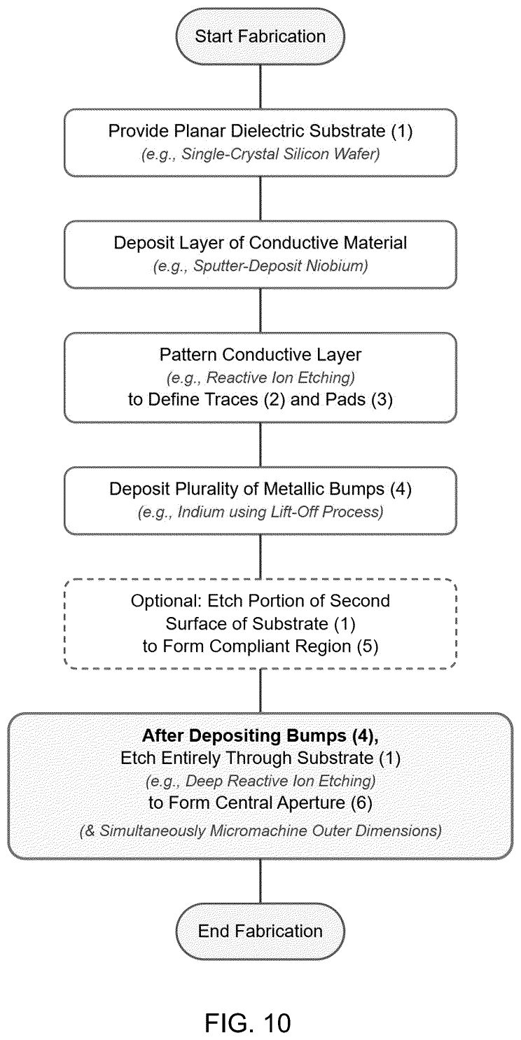

FIG. 10 is a flowchart that provides a schematic representation of a method for fabricating the interface probe card, illustrating a logical and novel sequence of microfabrication operations. The process initiates at a start block, “Start Fabrication,” and proceeds through a series of discrete yet interconnected manufacturing stages designed to construct the unique physical architecture of the apparatus. The first operational step in the flowchart is the provision of a planar dielectric substrate (1). This foundational step involves supplying a high-quality, uniform workpiece, such as a single-crystal silicon wafer, which serves as the mechanical and electrically insulating base for all subsequent features. The implementation of this step with a well-characterized material provides the benefit of a stable and predictable platform, which improves the accuracy and reliability of the high-precision lithographic and deposition steps that follow.

The method then progresses to the deposition of a layer of conductive material onto the first major surface of the substrate (1). This step functions to apply the raw material from which the card's high-frequency circuitry will be formed. An exemplary implementation of this step involves sputter-depositing a superconductive material, such as a thin film of niobium. The utility of this approach is the creation of a dense, uniform, and strongly adherent conductive layer, a benefit that provides for enhanced performance in the final device by ensuring the conductive traces (2) possess consistent and low-loss electrical properties, critical for high-bandwidth signal integrity.

Following deposition, the conductive layer is patterned. This step's function is to define the intricate geometry of the electrical network, and it is implemented using a technique like reactive ion etching (RIE). The outcome of this operation is the formation of the plurality of high-speed conductive traces (2) and the plurality of inner contact pads (3), which are arranged to circumscribe an interior region. The benefit of using an anisotropic etch process like RIE is the improved functionality of being able to create sharply defined features with high fidelity, which allows for denser and higher-performing waveguide structures. This process efficiently and accurately performs the task of creating the entire front-side electrical layout.

The flowchart then illustrates the deposition of the plurality of metallic bumps (4). This step functions to build the three-dimensional, protuberant structures that form the compliant interface for contacting a device under test (DUT) (200). A practical implementation involves using a lift-off process to deposit a soft metal, such as indium, precisely onto the inner contact pads (3). This specific choice of method provides the benefit of a more reliable manufacturing process for materials that are not easily etched, ensuring the accurate placement and formation of the bumps (4) that are essential for the probe card's improved functionality.

An optional step is shown for the creation of a compliant region (5), which involves etching a portion of the second major surface of the substrate (1). This step functions to engineer localized flexibility into the substrate (1) itself. The benefit of this non-obvious process step is an improved functionality in the final device, as the compliant region (5) allows for better contact uniformity and stress management during the bonding process, making the task of probing a device more reliable.

the final etch, which is performed after the deposition of the metallic bumps (4). This step functions to create the aperture (6) by etching entirely through the full thickness of the planar dielectric substrate (1), typically using a deep reactive ion etching (DRIE) process. The flowchart notes that this step may also be used to simultaneously micromachine the outer dimensions of the probe card. The primary benefit of this specific sequence is a novel and non-obvious solution to the manufacturing challenges of such a device. By preserving the mechanical integrity of the full substrate (1) throughout all front-side processing, this method prevents damage to the delicate, precision-aligned circuitry, thus performing the fabrication task more reliably and leading to a higher yield of functional devices with superior durability. The consolidation of the aperture etch with the final die singulation provides the further benefit of making the overall manufacturing process more efficient. The process concludes at an end block, “End Fabrication,” yielding a completed interface probe card with its full set of unique structural and functional features.

Established interfaces for the characterization of microelectronic devices are fundamentally defined by their physical structure, which has historically been one of considerable bulk and high profile. These conventional apparatuses, often constructed with thicknesses on the order of millimeters, create a complete physical overhang that entirely obscures the active surface of a device under test. This architectural paradigm consequently precludes any form of direct, top-down physical analysis, such as high-resolution microscopy, while the device is electrically connected and operational. A user was therefore forced into a significant compromise, able to either perform electrical measurements on an occluded device or physical measurements on a disconnected one, but critically unable to do both simultaneously. This limitation has impeded the direct correlation of real-time electrical behavior with localized physical phenomena, a significant barrier to the development and debugging of next-generation circuits.

The described interface probe card represents a fundamental topological departure from these established architectures. Its foundational distinction lies in the integration of an aperture (6) that extends entirely through an exceptionally low-profile planar dielectric substrate (1). This physical void, strategically located within the interior region defined by the geometric pattern of the inner contact pads (3), creates an unprecedented, direct and unmediated pathway from the external environment to the surface of a device under test (200). The critical outcome is the enablement of simultaneous, in-operando analysis, a new functional paradigm where a microscopy probe (201) can be positioned in close proximity to a device while that same device is fully powered and being stimulated with high-frequency signals transmitted through the plurality of high-speed conductive traces (2). This reconciles the historically mutually exclusive requirements of high-fidelity electrical probing and unobstructed physical access.

This novel topology is made possible through a synergistic combination of structural features and manufacturing techniques. The exceptionally low profile of the planar dielectric substrate (1), which can be fabricated to a thickness of less than 400 micrometers, minimizes the physical working distance for a microscopy probe (201), which is a significant factor in achieving higher resolution measurements. The monolithic construction of the apparatus, achieved through integrated microfabrication processes like deep reactive ion etching, allows for the creation of this unique structure with the aperture (6) in a way that is not feasible with the assembly methods used for many existing test interfaces. Furthermore, the compliance mechanism, provided by the plurality of metallic bumps (4) and, in some embodiments, the thinned compliant region (5), ensures that a reliable, low-resistance, multi-point electrical connection is maintained across the entire interface, even in the presence of microscopic non-planarity or thermally induced mechanical stress. This integrated, multi-level compliance system differs significantly from the rigid needle probes or less sophisticated contact schemes found in other test solutions.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix(s) as used herein is intended to include both the singular and the plural of the term that it modifies, thereby including at least one of that term (e.g., the colorant(s) includes at least one colorants). Option, optional, or optionally means that the subsequently described event or circumstance can or cannot occur, and that the description includes instances where the event occurs and instances where it does not. As used herein, combination is inclusive of blends, mixtures, alloys, reaction products, collection of elements, and the like.

As used herein, a combination thereof refers to a combination comprising at least one of the named constituents, components, compounds, or elements, optionally together with one or more of the same class of constituents, components, compounds, or elements.

All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It will also be understood that, although the terms first, second, etc. are, in some instances, used herein to describe various elements, these elements should not be limited by these terms. For example, a first current could be termed a second current, and, similarly, a second current could be termed a first current, without departing from the scope of the various described embodiments. The first current and the second current are both currents, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive; rather the elements can be used separately or can be combined together under appropriate circumstances.

### PARTS LIST

planar dielectric substrate 1
high-speed conductive traces 2
inner contact pads 3
metallic bumps 4
compliant region 5
aperture 6
device under test (DUT) 200
microscopy probe 201

What is claimed is:

1. An interface probe card, comprising:
a planar dielectric substrate (1) having a first major surface and a second major surface opposite the first major surface, wherein the planar dielectric substrate (1) is a cryogenic-compatible material;
a plurality of high-speed conductive traces (2) disposed on the first major surface of the substrate (1);
a plurality of inner contact pads (3) disposed on the first major surface, wherein each inner contact pad of the plurality of inner contact pads (3) is electrically connected to at least one of the plurality of high-speed conductive traces (2), the plurality of inner contact pads (3) arranged in a geometric pattern that defines an interior region;
a plurality of metallic bumps (4), each metallic bump of the plurality of metallic bumps (4) protruding from one of the plurality of inner contact pads (3); and
an aperture (6) extending entirely through the planar dielectric substrate (1) from the first major surface to the second major surface, the aperture (6) located within the interior region defined by the geometric pattern of the plurality of inner contact pads (3), wherein the aperture (6) provides an unobstructed line-of-sight path through the substrate (1).

2. The interface probe card of claim 1, wherein the planar dielectric substrate (1) is single-crystal silicon.

3. The interface probe card of claim 1, wherein the planar dielectric substrate (1) has a thickness of less than 400 micrometers.

4. The interface probe card of claim 1, wherein the plurality of high-speed conductive traces (2) are co-planar waveguides.

5. The interface probe card of claim 4, wherein the co-planar waveguides comprise a superconductive material.

6. The interface probe card of claim 5, wherein the superconductive material is niobium.

7. The interface probe card of claim 1, wherein the plurality of metallic bumps (4) comprise indium.

8. The interface probe card of claim 1, wherein a portion of the substrate (1) proximate to the plurality of inner contact pads (3) has a reduced thickness relative to other portions of the substrate (1), thereby forming a compliant region (5).

9. The interface probe card of claim 1, wherein the geometric pattern of the plurality of inner contact pads (3) is a perimeter array that peripherally surrounds the aperture (6).

10. The interface probe card of claim 1, wherein the planar dielectric substrate (1) is single-crystal silicon, the plurality of high-speed conductive traces (2) are co-planar waveguides comprising niobium, and the plurality of metallic bumps (4) comprise indium.

11. A method for probing a device under test, the method comprising:
providing an interface probe card comprising a planar dielectric substrate (1) having a first major surface and an opposing second major surface, a plurality of high-speed conductive traces (2) on the first major surface, a plurality of inner contact pads (3) electrically connected to the plurality of high-speed conductive traces (2) and arranged to define an interior region, a plurality of metallic bumps (4) protruding from the plurality of inner contact pads (3), and an aperture (6) extending entirely through the substrate (1) within the interior region;
aligning a device under test (DUT) (200) with the plurality of inner contact pads (3);
establishing simultaneous mechanical and electrical communication between the plurality of metallic bumps (4) and a corresponding plurality of contacts on the device under test (DUT) (200); and
accessing a surface of the device under test (DUT) (200) with a microscopy probe (201) through the aperture (6) of the interface probe card while the mechanical and electrical communication is maintained.

12. The method of claim 11, further comprising cooling the interface probe card and the device under test (DUT) (200) to a cryogenic temperature.

13. The method of claim 12, wherein the cryogenic temperature is less than 4 Kelvin.

14. The method of claim 11, further comprising transmitting electrical signals to the device under test (DUT) (200) via the plurality of high-speed conductive traces (2) and the plurality of metallic bumps (4).

15. The method of claim 14, wherein the electrical signals have a frequency in excess of 20 GHz.

16. The method of claim 11, wherein accessing the surface of the device under test (DUT) (200) comprises performing scanned probe microscopy.

17. The method of claim 16, wherein performing the scanned probe microscopy comprises performing scanned SQUID microscopy to characterize magnetic fields emanating from the surface of the device under test (DUT) (200).

18. The method of claim 17, wherein the device under test (DUT) (200) is a superconducting digital logic circuit.

19. The method of claim 11, wherein the method comprises the simultaneous steps of:
cooling the interface probe card and the device under test (DUT) (200) to a temperature of less than 4 Kelvin;
transmitting electrical signals having a frequency greater than 20 GHz to the device under test (DUT) (200); and
performing scanned SQUID microscopy on the surface of the device under test (DUT) (200) by positioning the microscopy probe (201) through the aperture (6).

20. The method of claim 11, wherein establishing the simultaneous mechanical and electrical communication comprises creating a semi-permanent die bond between the plurality of metallic bumps (4) and the corresponding plurality of contacts on the device under test (DUT) (200).

21. A method for fabricating an interface probe card, the method comprising:
providing a planar dielectric substrate (1) having a first major surface and a second major surface opposite the first major surface;
depositing a layer of a conductive material onto the first major surface of the planar dielectric substrate (1);
patterning the layer of the conductive material to define a plurality of high-speed conductive traces (2) and a plurality of inner contact pads (3), each of the plurality of inner contact pads (3) electrically connected to at least one of the plurality of high-speed conductive traces (2), wherein the plurality of inner contact pads (3) circumscribe an interior region of the first major surface;
depositing a plurality of metallic bumps (4), wherein each metallic bump of the plurality of metallic bumps (4) is deposited onto one of the plurality of inner contact pads (3); and
after depositing the plurality of metallic bumps (4), etching entirely through the planar dielectric substrate (1) from the first major surface to the second major surface to form an aperture (6) located within the interior region.

22. The method of claim 21, wherein providing the planar dielectric substrate (1) comprises providing a single-crystal silicon wafer.

23. The method of claim 21, wherein depositing the layer of the conductive material comprises sputter-depositing a superconductive material.

24. The method of claim 23, wherein the superconductive material is niobium.

25. The method of claim 21, wherein patterning the layer of the conductive material comprises performing reactive ion etching.

26. The method of claim 21, wherein depositing the plurality of metallic bumps (4) comprises depositing indium using a lift-off process.

27. The method of claim 21, wherein etching entirely through the planar dielectric substrate (1) comprises performing deep reactive ion etching.

28. The method of claim 27, further comprising micromachining the outer dimensions of the planar dielectric substrate (1) simultaneously with performing the deep reactive ion etching to form the aperture (6).

29. The method of claim 21, further comprising etching a portion of the second major surface of the substrate (1) to form a compliant region (5) with a reduced thickness, the compliant region (5) being located proximate to the plurality of inner contact pads (3).

30. The method of claim 21, wherein providing the planar dielectric substrate (1) comprises providing a single-crystal silicon wafer, wherein depositing the layer of the conductive material comprises depositing niobium, wherein depositing the plurality of metallic bumps (4) comprises depositing indium, and wherein etching entirely through the planar dielectric substrate (1) comprises performing deep reactive ion etching.
